(19) United States
(12) Patent Application Publication
(10) Pub. No.: US 2026/0076274 A1
(43) Pub. Date: Mar. 12, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Jae Jin Lee, Gyeonggi-do (KR); Seul Bee Lee, Incheon (KR); Hee Yong Park, Incheon (KR)

(73) Assignee: Amkor Technology Singapore Holding Pte. Ltd., Singapore (SG)

(21) Appl. No.: 19/323,956

(22) Filed: Sep. 9, 2025

Related U.S. Application Data
(60) Provisional application No. 63/693,973, filed on Sep. 12, 2024.

(51) Int. Cl. H01L 23/498; H01L 21/48; H01L 21/56

(52) U.S. Cl. CPC H10W 90/701; H10W 70/093; H10W 90/401; H10W 70/66; H10W 74/01

(57) ABSTRACT

In one example, an electronic device includes a first substrate, an electronic component disposed over a side of the first substrate, and a vertical interconnect structure coupled to the side of the first substrate. The vertical interconnect structure comprises a first metallic core structure coupled to the side of the first substrate, a second metallic core structure coupled to the first metallic core structure, and a fusible material coupling the first metallic core structure with the second metallic core structure. The fusible material also couples the first metallic core structure to the first substrate. A second substrate can be disposed over the electronic component and the vertical interconnect structure. The second metallic core structure of the vertical interconnect structure can be coupled to the second substrate by the fusible material. An encapsulant can be disposed over the electronic component. Other examples and related methods are also disclosed herein.

### CROSS REFERENCE TO RELATED APPLICATIONS

This application claims priority to U.S. Provisional Application No. 63/693,973 filed on Sep. 12, 2024, which is incorporated herein by reference.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 illustrates a cross-sectional view of an example electronic device.

FIGS. 2A-2I illustrate an example method for manufacturing an electronic device.

FIGS. 3A-3B illustrate an example method for manufacturing an electronic device.

FIGS. 4A-4B illustrate an example method for manufacturing an electronic device.

FIG. 5 illustrates a cross-sectional view of an example electronic device.

FIGS. 6A-6F illustrate an example method for manufacturing an electronic device.

FIG. 7 illustrates a cross-sectional view of an example electronic device.

FIG. 8 illustrates a cross-sectional view of an example electronic device.

FIGS. 9A-9D illustrate an example method for manufacturing an electronic device.

FIG. 10 illustrates a cross-sectional view of an example electronic device.

FIGS. 11A-11I illustrate an example method for manufacturing an electronic device.

FIG. 12 illustrates a cross-sectional view of an example electronic device.

FIGS. 13A-13C illustrate an example method for manufacturing an electronic device.

FIG. 14 illustrates a cross-sectional view of an example electronic device.

FIG. 15 illustrates a cross-sectional view of an example electronic device.

FIGS. 16A-16E illustrate an example method for manufacturing an electronic device.

The following discussion provides various examples of electronic devices and methods of manufacturing electronic devices. Such examples are non-limiting, and the scope of the appended claims should not be limited to the particular examples disclosed. The detailed description herein is presented for purposes of illustration only and not of limitation. For example, the steps recited in any of the method or process descriptions may be executed in any order and are not necessarily limited to the order presented. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term coupled can refer to an electrical coupling or a mechanical coupling.

### DESCRIPTION

An example electronic device can include a first substrate. An electronic component can be coupled to an inner side of the first substrate. A vertical interconnect structure can be coupled to the inner side of the first substrate and may include a core structure coupled to the first substrate, a wire coupled to the core structure and opposite the first substrate, and a first encapsulant disposed around the wire. The device also includes a second substrate disposed over the electronic component and coupled to the vertical interconnect structure.

Another example electronic device includes a first substrate, an electronic component disposed over an inner side of the first substrate, and a vertical interconnect structure disposed over the inner side of the first substrate. The vertical interconnect structure can include a metallic core ball coupled to the first substrate, a wire coupled to the metallic core ball opposite the first substrate, and a fusible material coupled to the metallic core ball, the wire, and the first substrate. A first encapsulant can be disposed around the wire with a tip of the wire protruding from the first encapsulant. The device also includes a second substrate disposed over the electronic component and the vertical interconnect structure. The wire of the vertical interconnect structure can be coupled to the second substrate. The device can also include an encapsulant disposed over the electronic component, around the metallic core ball, and between inner sidewalls of the first encapsulant.

An example method of making an electronic device can include the steps of providing a first substrate, providing a wire coupled to an inner side of the first substrate, providing a first encapsulant over and around the wire with a tip of the wire protruding from the first encapsulant, and providing a metallic core structure over the wire. A second substrate including an electronic component ban be provided, and a fusible material around the metallic core structure can be coupled to the second substrate and the wire. The method can include providing an encapsulant between the first substrate and the second substrate, over the electronic component, and around the metallic core structure.

Still another example electronic device can comprise a first substrate, an electronic component disposed over a side of the first substrate, and a vertical interconnect structure coupled to the side of the first substrate. The vertical interconnect structure can comprise a first metallic core structure coupled to the side of the first substrate, a second metallic core structure coupled to the first metallic core structure, and a fusible material coupling the first metallic core structure with the second metallic core structure. The fusible material can couple the first metallic core structure to the first substrate. A second substrate is disposed over the electronic component and the vertical interconnect structure. The second metallic core structure of the vertical interconnect structure is coupled to the second substrate by the fusible material. An encapsulant can be disposed over the electronic component, around the first metallic core structure and the second metallic core structure, and between the first substrate and the second substrate.

In another example, an electronic device can include a first substrate, an electronic component disposed over the first substrate, and a first interconnect structure coupled to the first substrate lateral to the electronic component. A second interconnect structure can be coupled to the first interconnect structure. A fusible material can couple the first interconnect structure with the second interconnect structure, and the first interconnect structure with the first substrate. A second substrate can be disposed over the electronic component and the second interconnect structure. The second interconnect structure can be coupled to the second substrate by the fusible material.

Another example method of manufacturing an electronic device can comprise the steps of providing a first substrate, providing an electronic component coupled to the first substrate, and providing a first interconnect structure coupled to the first substrate lateral to the electronic component. A second substrate can be provided, the second substrate comprising a second interconnect structure coupled to the second substrate. The first substrate and second substrate can be aligned with the first interconnect structure over the second interconnect structure. The first interconnect structure is coupled with the second interconnect structure using a fusible material.

Another example electronic device can include a first substrate, an electronic component coupled over a side of the first substrate, and a vertical interconnect structure coupled to the side of the first substrate. The vertical interconnect structure can comprise a first interconnect structure coupled to the side of the first substrate, and an intermediate substrate having a first side of the intermediate substrate coupled to the first interconnect structure opposite the first substrate. The intermediate substrate comprises inner sidewalls defining a cavity with the electronic component extending through the cavity. A second interconnect structure can be coupled to a second side of the intermediate substrate opposite the first side of the intermediate substrate. An encapsulant is disposed over the first substrate and the intermediate substrate, and disposed around the electronic component, the first interconnect structure, the second interconnect structure, and the intermediate substrate.

A further example electronic device comprises a first substrate, an electronic component coupled over a side of the first substrate, and a first interconnect structure coupled to the side of the first substrate. An intermediate substrate includes a first side of the intermediate substrate coupled to the first interconnect structure opposite the first substrate. The intermediate substrate defines a cavity with the electronic component extending through the cavity. A second interconnect structure can be coupled to a second side of the intermediate substrate opposite the first side of the intermediate substrate.

Yet another example method of making an electronic device can comprise the steps of providing a first substrate, coupling an electronic component to an inner side of the first substrate, providing an intermediate substrate including a first interconnect structure coupled to a first side of the intermediate substrate. Inner sides of the intermediate substrate can define an opening. The first interconnect structure is coupled to the inner side of the first substrate with the electronic component extending through the opening defined by the intermediate substrate. A second interconnect structure is coupled to a second side of the intermediate substrate opposite the first interconnect structure.

Other examples are included in the present disclosure. Such examples may be found in the figures, in the claims, or in the description of the present disclosure.

Electronic devices and related methods can incorporate relatively tall and narrow vertical interconnect structures between upper and lower substrates. The vertical interconnect structures can include conductive bodies (e.g., copper core balls, metallic core balls, wires, pillars, or other interconnects) stacked vertically in some examples to support a thick-cavity interposer. For example, a wire can be coupled to a copper core ball or other conductive structure to form a tall interconnect structure with narrow pitch or high density. The use of tall vertical interconnect structures can enable the use of a thicker die in electronic devices, which can improve thermal performance.

In some examples, the thickness of electronic components included in the thick-cavity interposers can be greater than approximately 50 micrometers (μm). As used herein with references to numeric values, the term approximately can mean +/−5%, +/−10%, +/−15%, +/−20%, or +/−25%. In some examples, die thickness can range up to approximately 450 μm. In some examples, die thickness can be approximately 300 μm, approximately 350 μm, approximately 400 μm, or approximately 450 μm. Shorter or taller electronic components can be used in other examples.

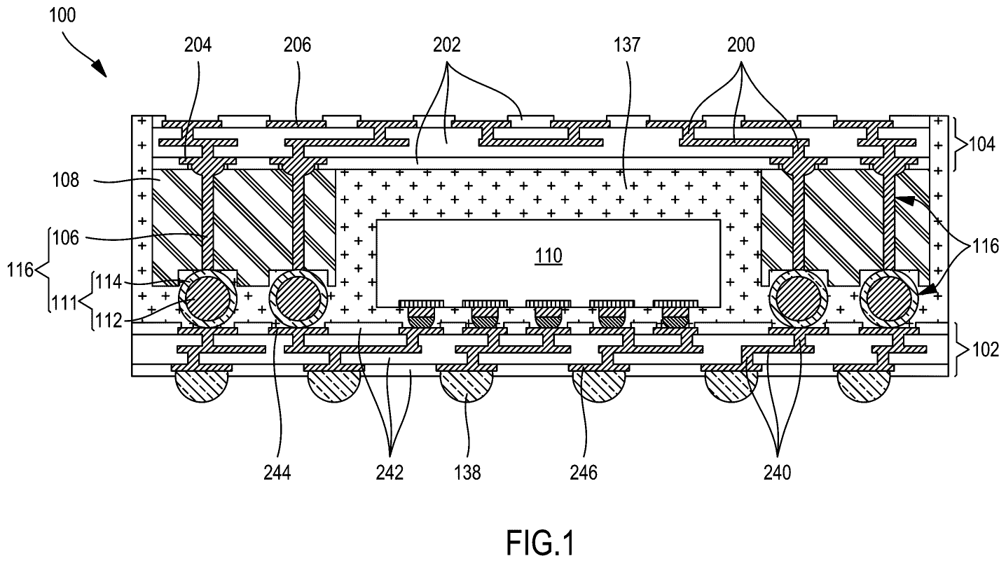

Referring now to FIG. 1, a cross-sectional view of example electronic device 100 is shown. In the example of FIG. 1, electronic device 100 can comprise electronic component 110, vertical interconnects 116, substrate 102, and substrate 104. In some examples, electronic device 100 can comprise external interconnects 138, encapsulant 137, or encapsulant 108. Encapsulant 108 can be disposed around vertical interconnects 116. Vertical interconnects 116 can comprise wires 106 and interconnect structures 111. In some examples, vertical interconnects 116 can comprise pillars, vias, posts, pins, or other narrow interconnects coupled to interconnect structures 111. In some examples, a height to width ratio of the narrow interconnect of vertical interconnect 116 can be between 2:1 and 20:1, or between 4:1 and 15:1. For example, the narrow interconnect of vertical interconnect 116 can have a height to width ratio of at least 2:1, 3:1, 4:1 10:1 or 16:1.

In various examples, core structure 112 can couple wire 106 to substrate 102. Core structure 112 can comprise metallic core balls, metallic pins, metallic pillars, or other conductive structures. Core structure 112 can comprise a metal (e.g., copper or other metal) or alloy inner core with a flowable material disposed around the inner core. Core structure 112 can be coupled to wire 106 by fusible material 114. Substrate 102 can be electrically coupled to substrate 104 through vertical interconnect 116, which can comprise core structure 112, fusible material 114, and wire 106. Vertical interconnects 116 can be arranged with a fine pitch while supporting increased height of vertical interconnects 116. The thickness of electronic component 110 can be increased, as the volume between substrate 102 and substrate 104 is increased by increasing the height of vertical interconnect 116. In some examples, the height of electronic component 110 can approach the height of wire 106 or of vertical interconnect structure 116.

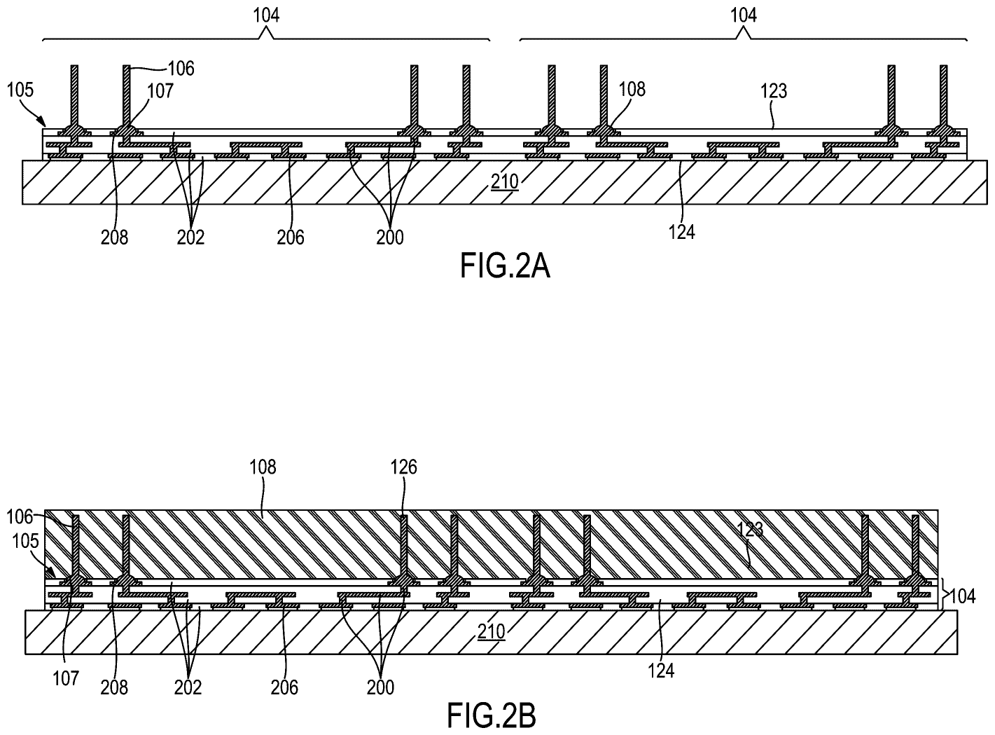

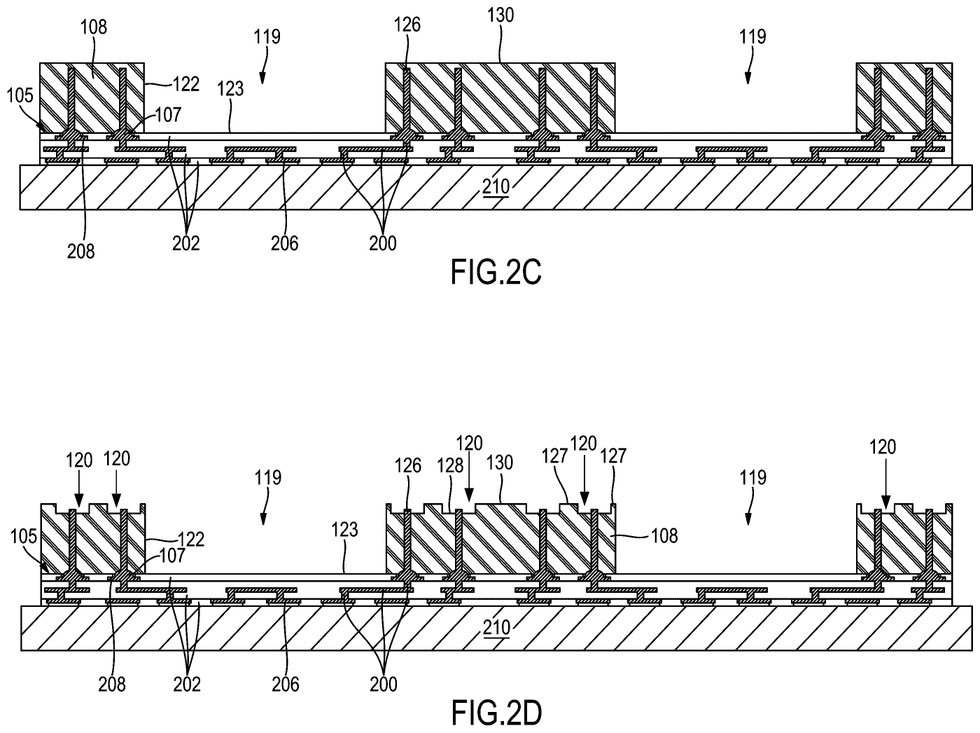

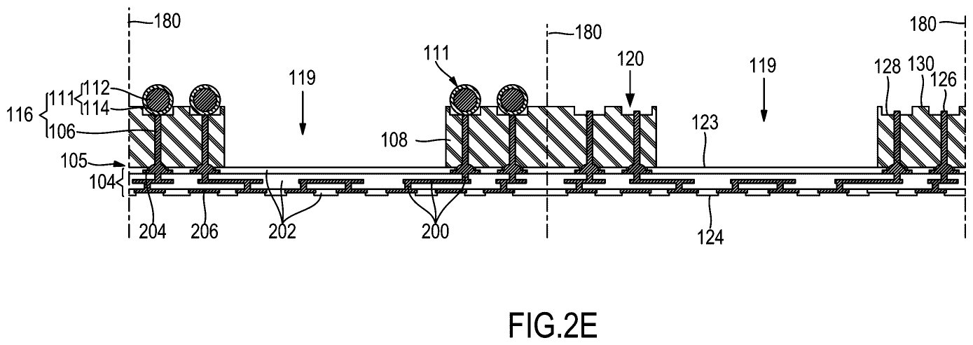

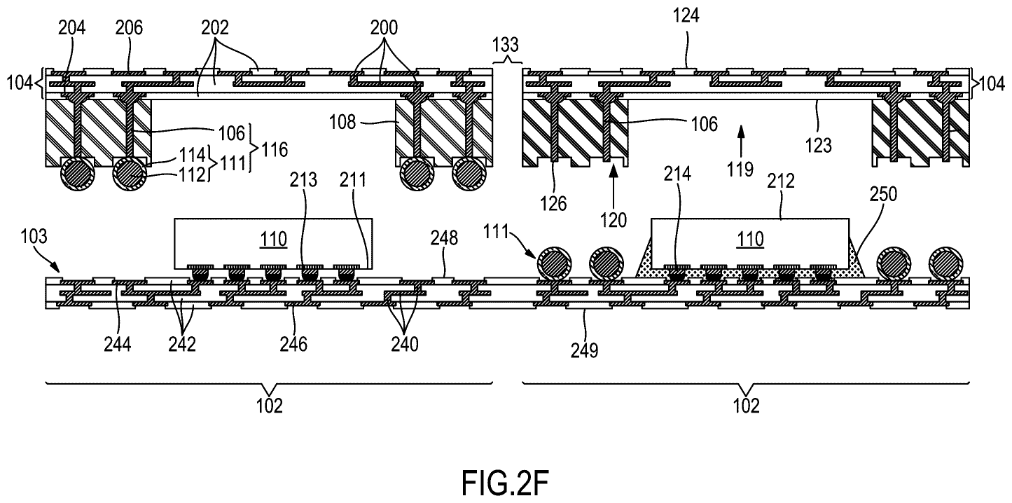

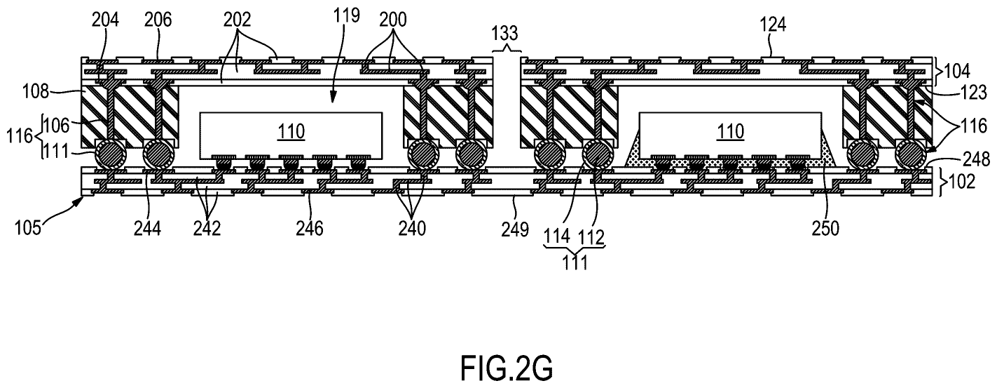

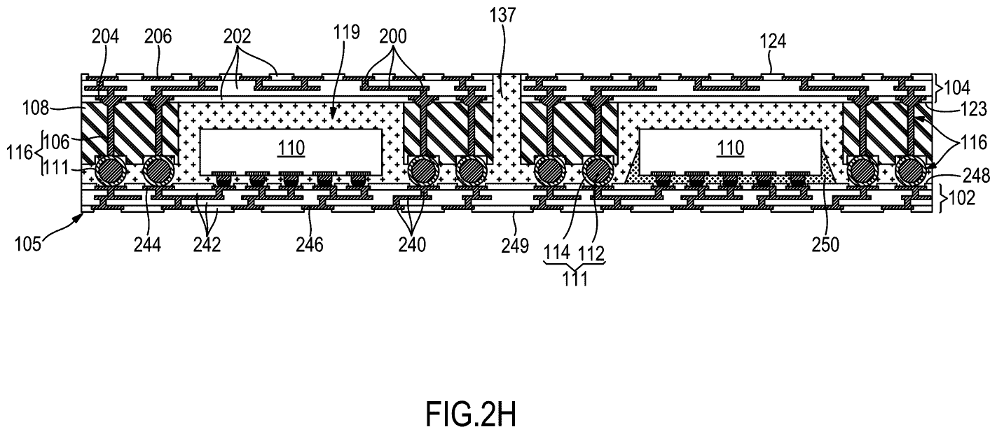

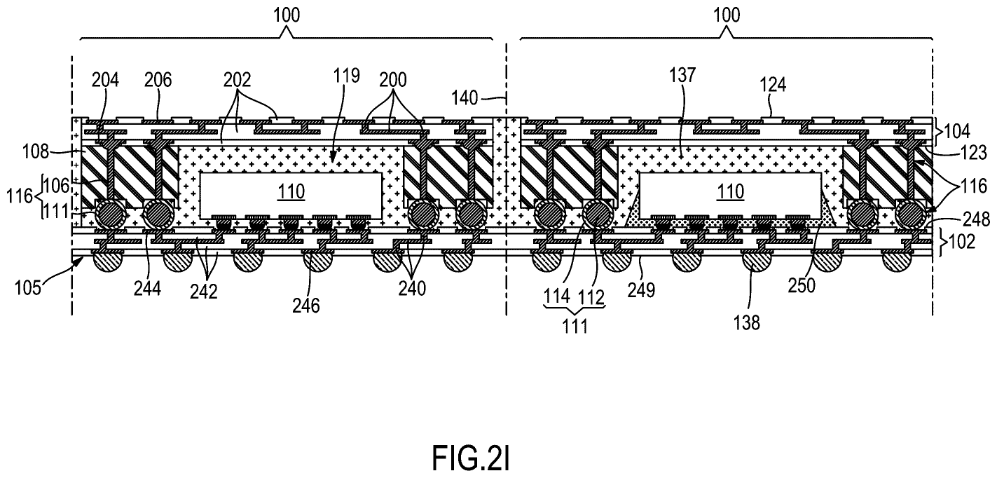

FIGS. 2A-2I show an example method for manufacturing electronic device 100 using cross-sectional views, in accordance with various examples. In the example of FIG. 2A, wires 106 (or similar tall and narrow conductive structures) can be provided over substrates 104.

In some embodiments, substrates 104 can be provided as part of a strip 105 of substrates 104. Substrate strip 105 can include multiple adjacent, connected substrates 104. In some embodiments, substrates 104 can be provided as one or more separate, discrete substrates over carrier 210.

In some examples, carrier 210 can be a substantially planar support. Carrier 210 can comprise or be referred to as a plate, a board, a wafer, or a panel. For example, carrier 210 can be made of steel, stainless steel, aluminum, copper, ceramic, glass, or semiconductor material. Carrier 210 can support and enable the handling of multiple substrates 104 during the process of providing electronic devices 100. Multiple substrates 104 can be provided as one or more strip(s) of substrate(s), singulated substrates, or in wafer form in a grid, an array, rows, columns, or other arrangements on carrier 210.

In some examples, carrier 210 can comprise a temporary bond layer provided on the surface of carrier 210. Outer terminals 206 can be provided over the temporary bond layer of carrier 210. In some examples, the temporary bond layer can comprise or be referred to as a temporary adhesive film, a temporary adhesive tape, or a temporary adhesive coating. For example, the temporary bond layer can be a heat release tape (film) or an optical release tape (film), and the adhesive strength can be weakened or removed by heat or light, respectively. In some examples, the temporary bond layer can have the adhesive strength weakened or removed by chemical or external force. The temporary bond layer can allow carrier 210 to be separated from substrates 104.

In various examples, substrate 104 can comprise conductive structure 200 and dielectric structure 202. In some examples, dielectric structure 202 can comprise or be referred to as one or more stacked dielectric layers. For instance, the one or more dielectric layers can comprise one or more core layers, polymer layers, pre-preg layers, solder mask layers, or the like stacked on each other. One or more layers or elements of conductive structure 200 can be interleaved with elements or layers of dielectric structure 202. In some examples, dielectric structure 202 can comprise polymer, bismaleimide triazine (BT), polyimide (PI), benzocyclobutene (BCB), polybenzoxazole (PBO), Ajinomoto Buildup Film (ABF), resin, mold compound, ceramic, glass, silicon, copper clad laminate, or flame retardant material (e.g., FR4 comprising laminated layers of copper foil and glass fiber fabric). Dielectric structure 202 can maintain the shape of substrate 104 and can structurally support conductive structure 200. In some examples, the thickness of dielectric structure 202 can range from approximately 5 μm (micrometers) to approximately 100 μm, approximately 10 μm to approximately 50 μm, approximately 10 μm to approximately 35 μm, or approximately 2 μm to approximately 10 μm. The thickness of dielectric structure 202 can refer to individual layers of dielectric structure 202. The overall thickness of dielectric structure 202 can provide or be generally equal to the thickness of substrate 104. In some examples, substrate 104 can have a thickness range from approximately 10 μm to approximately 1000 μm, 50 μm to approximately 500 μm, approximately 25 μm to 200 μm, or approximately 10 μm to approximately 50 μm.

Conductive structure 200 can comprise or be referred to as one or more conductive layers defining signal distribution elements, traces, vias, pads, conductive patterns, conductive paths, wiring patterns, circuit patterns, or under bump metallization (UBM). In some examples, conductive structure 200 can comprise one or more layers of copper (Cu), aluminum (Al), tin (Sn), titanium (Ti), titanium tungsten (TiW), gold (Au), silver (Ag), nickel (Ni), palladium (Pd), combinations or alloys thereof, or the like. The layers and elements of conductive structure 200 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or any other suitable metal deposition process. The thickness of conductive structure 200 can range from approximately 1 μm to approximately 50 μm, for example from approximately 2 μm to approximately 20 μm, for example from approximately 2 μm to approximately 10 μm. The thickness of conductive structure 200 can refer to individual layers of conductive structure 200. Conductive structure 200 can provide electrical signal paths (e.g., vertical paths and horizontal paths) through dielectric structure 202.

Conductive structure 200 can be exposed at outer side 124 of substrate 104 and can comprise outer terminals 206 along outer side 124 of substrate 104. Conductive structure 200 can be exposed at inner side 123 of substrate 104 and can comprise inner terminals 208 along inner side 123 of substrate 104. In some examples, inner terminals 208 and outer terminals 206 can comprise or be referred to as pads, lands, studs, or UBM. Layers and elements of conductive structure 200 can electrically couple inner terminals 208 with outer terminals 206.

In some examples, substrate 104 can be a pre-formed substrate. Pre-formed substrates can be manufactured prior to attachment to an electronic device and can comprise dielectric layers between respective conductive layers, for example layers of dielectric structure 202 between layers of conductive structure 200. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. In examples where the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4. In some examples, the core structure can comprise glass. The dielectric and conductive layers can be provided on the permanent core structure. In other examples, the pre-formed substrate can be a coreless substrate omitting the permanent core structure, and the dielectric and conductive layers can be provided on a sacrificial carrier that is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process.

In some examples, substrate 104 can be a redistribution layer (“RDL”) substrate. RDL substrates can comprise one or more conductive redistribution layers, for example conductive structure 200, and one or more dielectric layers, for example dielectric structure 202, that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly formed with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal.

The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film.

To permit proper formation of desired photo-defined features, such photo-definable dielectric materials can omit structural reinforcers or can be filler-free, without strands, weaves, or other particles, which could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layers can comprise silicon nitride (Si3N4), silicon oxide (SiO2), or silicon oxynitride (SiON). The inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, RDL substrate can be referred to as a build-up substrate. RDL substrates can omit the permanent core or carrier structure generally associated with preformed, laminate substrates, as described above. The minimum trace width and trace spacing of RDL substrates can be less than the minimum trace width and trace spacing associated with pre-formed substrates. RDL substrates can provide a greater trace density and/or smaller pitch, as compared to preformed substrates.

In various examples, one or more layers or elements of conductive structure 200 can be interleaved with dielectric structure 202, and dielectric structure 202 and conductive structure 200 can include any number of layers in substrate 104. Inner terminals 208 and outer terminals 206 can be spaced apart in rows, columns, arrays, or other arrangements on opposing sides of substrate 104. In some examples, a single layer of conductive structure 200 or a single layer of dielectric structure 202 could range from approximately 4 μm to approximately 40 μm, from approximately 4 μm to approximately 25 μm, or from approximately 5 μm to approximately 12 μm. Substrate 104 can comprise any number of layers such as, for example, one to ten layers or two to five layers. Substrates in this disclosure can comprise pre-formed substrates or RDL substrates.

In accordance with various examples, wires 106 or other narrow interconnects, can be provided over inner side 123 of substrate 104. Wires 106 can be coupled to conductive structure 200. For example, wires 106 can be coupled to and/or contacting inner terminals 208 of conductive structure 200. Wires 106 can be coupled to inner terminals 208 via wire bond 107. In some examples, wire 106 can have a height ranging from approximately 290 μm to approximately 800 μm. Wire 106 can have a diameter or width from approximately 18 μm to approximately 220 μm. In some examples, wire 106 can have a diameter less than approximately 20 μm, approximately 30 μm, or approximately 40 μm. The pitch of vertical interconnects 116 can be approximately 200 μm, approximately 220 μm, approximately 240 μm, or approximately 260 μm in some examples with thick wires. In some examples, wire diameter can approximate pitch.

FIG. 2B shows electronic device 100 at a later stage of manufacture, in accordance with various examples. In the example of FIG. 2B, encapsulant 108 can be provided over substrate 104 and wires 106.

In various examples, encapsulant 108 can have a substantially planar upper side 130 and can extend above tips 126 of wires 106. As used herein with qualitative phrases such as substantially planar, for example, the term substantially can mean within manufacturing tolerances. Wires 106 can be covered by encapsulant 108.

In various examples, encapsulant 108 can comprise or be referred to as a package body, an encapsulating structure, an insulator, a mold, a mold structure, an epoxy molding compound (EMC), a resin, a filler-reinforced polymer, a B-stage compressed film, gel, etc. Encapsulant 108 can be provided by transfer molding, compression molding, liquid encapsulant molding, vacuum lamination, paste printing, film assisted molding, or any other suitable process.

FIG. 2C shows electronic device 100 at a later stage of manufacture, in accordance with various examples. In the example of FIG. 2C, a portion of encapsulant 108 can be removed from over substrate 104 to expose inner side 123 of substrate 104. Portions of encapsulant 108 can be removed using etching, grinding, or laser ablation, for example.

In various examples, removal of encapsulant 108 can provide cavity 119 over substrate 104. Cavity 119 can be defined by interior sidewalls 122 of encapsulant 108 and inner side 123 of substrate 104. Cavity 119 can be configured to receive an electronic component at a later stage of manufacture.

FIG. 2D shows electronic device 100 at a later stage of manufacture, in accordance with various examples. In the example of FIG. 2D, a portion of encapsulant 108 can be removed to expose tips 126 of wires 106.

In various examples, removing encapsulant 108 and exposing tips 126 can create protrusions 127 extending from recessed side 128 of encapsulant 108. Protrusion 127 can be between tips 126 of wires 106. Cavities 120 in encapsulant 108 can be defined between adjacent protrusions 127 and by recessed side 128. Recessed side 128 can be lower than or recessed from upper side 130 of encapsulant 108 and from upper sides of protrusions 127 and tips 126 of wires 106. Cavities 120 can be sized to receive core structures 112 (e.g., copper core balls) at a later stage of manufacture.

FIG. 2E shows electronic device 100 at a later stage of manufacture, in accordance with various examples. In the example of FIG. 2E, interconnect structures 111 can be provided. In various examples, interconnect structures 111 can include core structures 112 and fusible material 114.

In various examples, core structures 112 can comprise metallic core balls, metallic pins, or metallic pillars. Fusible material 114 can be provided around core structures 112. Core structures 112 can be coupled to tip 126 of wire 106 exposed over cavity 120. Core structures 112 can be in contact with or spaced apart from tip 126 of wire 106. Protrusions 127 can inhibit lateral movement of core structures 112 and can retain core structures 112 over wires 106. A thermocompression, reflow, or laser assisted bonding process can be performed to couple cores structures 112 to tip 126 of wire 106 using fusible material 114.

In the example shown in FIG. 2E, singulation can also be performed. In accordance with various examples, singulation can be performed by cutting through saw streets, for example indicated by lines 180, disposed around a perimeter of substrates 104, thereby separating individual substrates 104 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate 104 and encapsulant 108. In some examples, after singulation, encapsulant 108 can be coplanar with the lateral sides of substrate 104. In some examples, after singulation, vertical interconnects 116 can be located in an edge region of substrate 104. For example, vertical interconnects 116 can be between cavity 119 and the lateral sides of substrate 104.

In accordance with various examples, carrier 210 can be removed before or after singulation. In some examples, carrier 210 and its temporary bond layer can be separated from substrates 104. In some examples, the temporary bond layer can have an adhesive strength weakened or removed responsive to physical force, chemical force, heat, or light. Removal of carrier 210 and its temporary bond layer can release substrates 104 for positioning over substrates 102, as described below.

FIG. 2F shows electronic device 100 at a later stage of manufacture, in accordance with various examples. In the example of FIG. 2F, substrates 104 can be provided over substrates 102.

In some examples, vertical interconnects 116 can be coupled to substrate 104 with interconnect structure 111 oriented toward substrates 102. Pick-and-place equipment can pick up substrates 104 and align vertical interconnects 116 on inner terminals 244 of substrate 102. In some examples, interconnect structure 111 of vertical interconnects 116 can be coupled to substrate 102, and substrate 104 can be disposed over interconnect structure 111 with tips 126 of wires 106 oriented toward and aligned with interconnect structures 111.

In some embodiments, substrate 102 can be provided as part of a strip 103 of substrates 102. Substrate strip 103 can include multiple adjacent, connected substrates 102. In some embodiments, substrates 102 can be provided as one or more separate individual substrates, for example coupled to a carrier. Substrate 102 can include inner side 248 and outer side 249 opposite inner side 143.

In accordance with various embodiments, substrate 102 can comprise dielectric structure 242 and conductive structure 240. Conductive structure 240 and dielectric structure 242 of substrate 102 can comprise structures and manufacturing techniques similar to or the same as those of conductive structure 200 and dielectric structure 202, respectively, of substrate 104. Conductive structure 240 can be exposed at inner side 248 and outer side 249 of substrate 102. Conductive structure 240 can comprise inner terminals 244 provided along inner side 248 of substrate 102, and outer terminals 246 provided along outer side 249 of substrate 102. In some examples, inner terminals 244 and outer terminals 246 can comprise or be referred to as pads, lands, or UBM. Layers and elements of conductive structure 204 can electrically couple inner terminals 244 with outer terminals 246.

In some examples, elements, features, materials, or manufacturing methods of substrate 102 can be similar to or the same as those of substrate 104. Substrate 102 can comprise a core or be coreless. In some examples, substrate 102 can comprise or be referred to as a pre-formed or laminate substrate, as previously described. In some examples, substrate 102 can comprise or be referred to as an RDL or build-up substrate, as previously described. In examples where substrate 102 comprises an RDL substrate, substrates 104 can be disposed over substrates 102 with a support carrier coupled to outer side 249 of substrates 102.

In accordance with various examples, one or more electronic component(s) 110 can be provided over inner side 248 of substrate 102. Electronic component(s) 110 can be coupled to conductive structure 240 of substrate 102. For example, electronic component(s) 110 can be coupled to inner terminals 244 of conductive structure 240.

Electronic component 110 can comprise proximal side 211 facing substrate 102 and distal side 212 opposite proximal side 211. In some examples, proximal side 211 can comprise or be referred to as an active side of electronic component 110. Electronic component 110 can include contacts 213 on the active side of electronic component 110. Contacts 213 can comprise or be referred to as contact pads or bond pads, in some examples. In some examples, contacts 213 can comprise a metal exposed via an inorganic dielectric material such as silicon dioxide (SiO2) or silicon nitride (Si3N4) located over the active side of electronic component 110. For example, contacts 213 can be the final metal layer formed at the back-end-of-line (BEOL) stage. In some examples, contacts 213 can be exposed via an organic dielectric material or a solder resist material formed over the BEOL layers.

In some examples, connectors 214 can couple electronic component 110 to substrate 102. Connectors 214 can couple contacts 213 of electronic component 110 to inner terminals 244. Connectors 214 can comprise or be referred to as bumps, tin-lead (SnPb) bumps, lead-free bumps, copper pillars, stud bumps, pillars, posts, solder capped metal pillars, etc.

In accordance with various examples, electronic component 110 can comprise or be referred to as a die, chip, semiconductor package (e.g., multiple interconnected and/or stacked die and/or one or more die coupled to an interposer), passive component, antenna patch, or power device. In some examples, electronic component 110 can comprise a digital signal processor (DSP), network processor, power management unit, audio processor, radio-frequency (RF) circuit, wireless baseband processor, system-on-chip (SoC) processor, sensor, or application-specific integrated circuit (ASIC). In some examples, electronic component 110 can be configured to perform calculation and control processing, store data, or remove noise from electrical signals.

In some examples, pick-and-place equipment can pick up electronic components 110 and place electronic components 110 on inner side 248 of substrates 102. Connectors 214 can be positioned on top of inner terminals 244 of substrate 102. Subsequently, contacts 213 of electronic component 110 can be coupled to inner terminals 244 by means of bonding connectors 214 to inner terminals 244 using, for example, a reflow, thermal-compression, or laser assisted bonding process. While electronic components 110 are shown in flip-chip configuration with contacts 213 oriented toward substrate 102, there can be examples where one or more electronic components 110 are oriented in a face-up or wire-bond configuration with contacts 213 oriented away from substrate 102 and connectors 214 comprising wire bonds, for example.

In some examples, underfill 250 can be disposed between electronic component 110 and substrate 102, before or after placement and/or coupling of electronic component 110 on substrate 102. Underfill 250 can include a liquid molding compound (LMC), a capillary underfill (CUF), a nonconductive paste (NCP), or the like. In some examples, underfill 250 can be applied to electronic component 110 or to by dispensing or printing.

FIG. 2G shows electronic device 100 at a later stage of manufacture, in accordance with various examples. In the example of FIG. 2G, vertical interconnects can be coupled to substrate 102.

In various examples, individual substrates 104 can be aligned over substrates 102 with gap 133 defined between outer sidewalls of encapsulant 108 of adjacent substrates 104. Core structures 112 and wires 106 can be aligned over inner terminals 244 of substrate 102. In some examples, a thermocompression, reflow, or laser assisted bonding process can be performed to couple core structures 112 to inner terminals 244 through fusible material 114. In some examples, vertical interconnects 116 can comprise wires 106 and interconnect structures 111. Interconnect structures 111 can comprise fusible material 114 and core structures 112. In some examples, substrate 104 can be in electronic communication with substrate 102 through vertical interconnects 116. Electronic components 110 can be electrically coupled to vertical interconnects 116 via conductive structure 240.

In some examples, vertical interconnects 116 can have a height greater than the height of electronic component 110. Vertical interconnects 116 can comprise a pitch or density limited by the width or diameter of core structure 112. For example, copper core balls can have a diameter greater than the width of individual wires 106. Core structure 112 can be a limiting factor in pitch density of vertical interconnects 116. However, the tall, narrow structure of wires 106 can allow for smaller diameter core structures 112, which can decrease the pitch of vertical interconnects 116. In some examples, die thickness of electronic components 110 can reach up to approximately 450 μm or more. In some examples, thickness of electronic component 110 can be approximately 300 μm, approximately 350 μm, approximately 400 μm, or approximately 450 μm. Greater die thickness can result in improved thermal properties in some examples. By enabling greater die thickness with relatively narrow pitch vertical interconnects 116 can improve thermal properties of electronic device 100.

FIG. 2H shows electronic device 100 at a later stage of manufacture, in accordance with various examples. In the example of FIG. 2H, encapsulant 137 can be provided. Encapsulant 137 can be disposed around lateral sides of fusible material 114 and core structure 112. Encapsulant 137 can be coupled to the interior sidewalls 122 and exterior sidewalls of encapsulant 108. Encapsulant 137 can extend between adjacent substrates 104 in the example of FIG. 2H.

In some examples, encapsulant 137 can cover distal side 212 of electronic component 110. Encapsulant 137 can surround the lateral sides of electronic component 110. In some examples, encapsulant 137 extend between the inner side 248 of substrate 102 and the inner side 123 of substrate 104. In some examples, encapsulant 137 extend between the inner side 248 of substrate 102 and proximal side 211 of electronic component 110.

In various examples, encapsulant 137 can comprise or be referred to as a package body, an encapsulating structure, an insulator, a mold, an epoxy molding compound (EMC), a resin, a filler-reinforced polymer, a B-stage compressed film, gel, etc. Encapsulant 108 can be provided by transfer molding, compression molding, liquid encapsulant molding, vacuum lamination, paste printing, film assisted molding, or any other suitable process. In some examples, the material of encapsulant 108 can be different from the material of encapsulant 137. In some examples, encapsulant 108 and encapsulant 137 can comprise the same material.

FIG. 2I shows electronic device 100 at a later stage of manufacture, in accordance with various examples. In the example of FIG. 2I, external interconnects 138 can be provided.

In some examples, external interconnects 138 can be located on the outer side 249 of substrate 102. External interconnects 138 can be disposed on and coupled to outer terminals 246 of conductive structure 240. External interconnects 138 can be electrically coupled to electronic components 110 via conductive structure 240. In some examples, external interconnects 138 can comprise tin (Sn), silver (Ag), lead (Pb), copper (Cu), Sn-Pb, Sn37-Pb, Sn95-Pb, Sn-Pb-Ag, Sn-Cu, Sn—Ag, Sn-Au, Sn-Bi, or Sn—Ag—Cu. For example, external interconnects 138 can be provided by forming a conductive material including solder on outer terminals 246 through a ball drop method followed by a reflow process. External interconnects 138 can comprise or be referred to as solder balls, bumps, pads, or pillars. In some examples, the sizes of external interconnects 138 can range from approximately 10 μm to approximately 1,000 μm.

In some examples, external interconnects 138 can comprise conductive balls or bumps (e.g., solder balls, solder bumps, wafer bumps, solid core solder balls, or copper core solder balls). In some examples, external interconnects 138 can comprise conductive pillars or posts, wires, lands, or pads, and can comprise any of a conductive material (e.g., a metal or a conductive adhesive). In some examples, external interconnects 138 can be referred to as external input/output terminals of electronic device 100. In some examples, electronic device 100 can be implemented in a land grid array (LGA) configuration and outer terminals 246 of substrate 102 can serve as external input/output terminals. In such examples, electronic device 100 can be devoid of external interconnects 138.

In the example of FIG. 2I, singulation can also be performed. In some examples, a singulation process can be performed after providing external interconnects 138.

In various examples, singulation can be performed by sawing or otherwise cutting through saw streets, for example indicated by lines 140, disposed around a perimeter of electronic devices 100, thereby separating individual electronic devices 100 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate 102 and encapsulant 137. In some examples, after singulation, encapsulant 137 can be coplanar with the lateral sides of substrate 102 and surround the lateral sides of substrate 104 and/or the exterior lateral sides of encapsulant 108. In some examples, saw streets 140 may be configured such that encapsulant 137 is removed from the exterior lateral sides of encapsulant 108 and/or the lateral sides of substrate 104. In such examples, encapsulant 137 can be coplanar with the lateral sides of substrate 102, the lateral sides of encapsulant 108, and/or the lateral sides of substrate 104. In some examples, substrates 104, having vertical interconnects 116 and encapsulant 108 on inner side 123, can be disposed over substrates 102 in strip form. For example, substrate strip 105, as shown FIG. 2E, can be disposed over substrates 102, without performing singulation through saw streets 180 (FIG. 2E). In this regard, the singulation of FIG. 2I, can be performed through substrate 104, encapsulant 108, encapsulant 137, and substrate 102, and in electronic device 100 encapsulant 137 can be coplanar with the lateral sides of substrate 102, the lateral sides of encapsulant 108, and/or the lateral sides of substrate 104.

In some examples, after singulation, vertical interconnects 116 can be located in an edge region of electronic device 100, for example at edge regions of substrate 102. For example, vertical interconnects 116 can be between electronic components 110 and the lateral sides of substrate 102 and/or between electronic components 110 and the lateral sides of substrate 104.

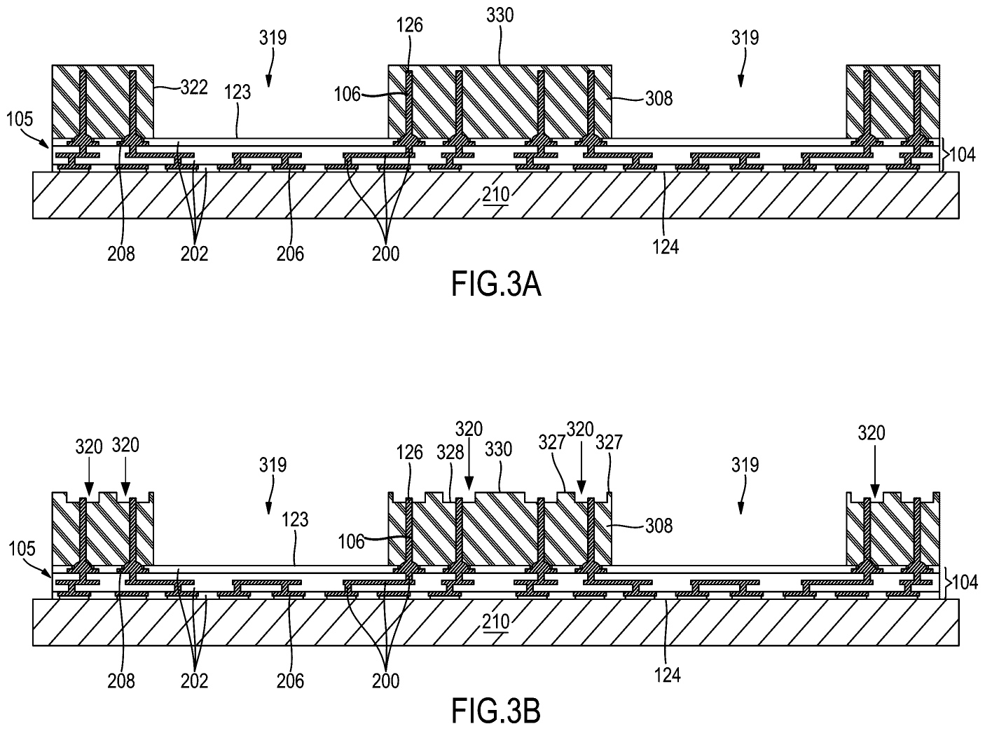

FIGS. 3A and 3B show a method for making electronic device 100 using cross-sectional views, in accordance with various embodiments. The steps shown in FIGS. 3A and 3B can be substituted after the step shown in FIG. 2A into the example method depicted in FIGS. 2A-2I and described above.

In the example of FIG. 3A, encapsulant 308 (also referred to as a partial mold structure) is provided over substrate 104. Encapsulant 308 can comprise structures and manufacturing techniques similar to or the same as those of encapsulant 108 (of FIG. 2B). Encapsulant 308 can comprise interior sidewalls 322 defining cavity 319 over substrate 104. Encapsulant 308 can have a height greater than the height of wires 106. Encapsulant 308 can cover wires 106 in the example of FIG. 3A. In some examples, a mask or temporary material can be placed over inner side 123 of substrate 104 during formation of encapsulant 308, and the mask or temporary material can then be removed leaving a portion of inner side 123 exposed from encapsulant 308.

FIG. 3B shows electronic device 100 at a later stage of manufacture, in accordance with various examples. In the example of FIG. 3B, a portion of encapsulant 308 can be removed to expose tips 126 of wires 106. The structures and manufacturing techniques of FIG. 3B can be similar to or the same as those depicted in FIG. 2D and described above. Cavities 320 can be defined between protrusions 327. Cavities 320 can be defined by recessed side 328, which can be recessed from upper side 330 of encapsulant 308. Wires 106 can protrude from the recessed side 328 of encapsulant 308. After performing the steps of FIG. 3B, an example method can continue implementing structures and manufacturing techniques similar to or the same as those described above and depicted in FIGS. 2E through 2I.

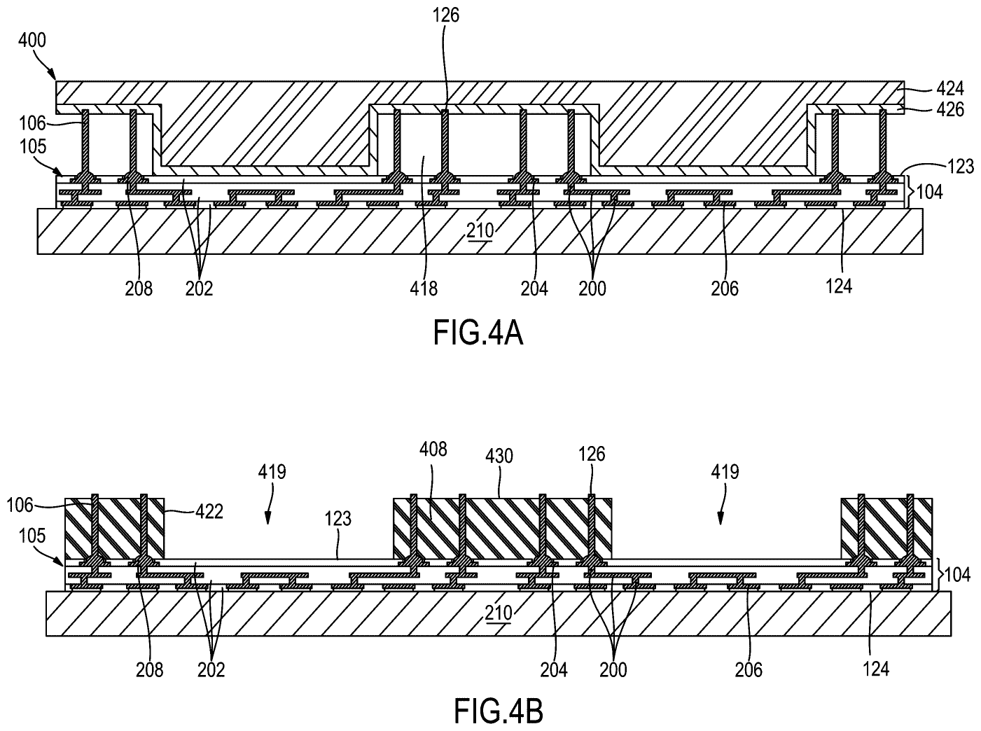

FIGS. 4A and 4B show a method for making electronic device 100 using cross-sectional views, in accordance with various embodiments. The steps shown in FIGS. 4A and 4B can be substituted after the step shown in FIG. 2A into the example method depicted in FIGS. 2A-2I and described above in some examples, though structures on the upper side of encapsulant 408 can be substantially planar.

The example of FIG. 4A shows a mold chase 424 and a mold film 426 over substrates 104. Tips 126 of wires 106 extend into film 426. Wires 106 may contact or be separated from mold chase 424. Mold film 426 can contact substrate 104. For example, film 426 can contact inner side 123 of substrate 104. Mold openings 418 can be defined between substrate 104 and mold film 426 or mold chase 424. Mold openings 418 can contain portions of wires 106 exposed from mold film 426.

In the example of FIG. 4B, encapsulant 408 can be provided in mold openings 418 (FIG. 4A) defined between mold film 426 and substrate 104. Encapsulant 408 can fill mold openings 418. Encapsulant 408 can be disposed over substrate 104 and around wires 106. Mold chase 424 and mold film 426 can be removed leaving a cavity 419 defined by sidewalls 422 of encapsulant 408 and inner side 123 of substrate 104. Tips 126 of wires 106 can protrude from and be exposed from upper side 430 of encapsulant 408. In some examples, laser ablation or other removal processes can be performed to remove a portion of encapsulant 408 forming protrusions 127 (of FIG. 2D) cavities 120 (of FIG. 2D). After performing the steps of FIG. 4B, an example method can continue using structures and manufacturing techniques similar to or the same as those of FIGS. 2E through 2I, but with upper side 430 of encapsulant 408 being substantially planar.

Electronic devices and related manufacturing techniques can use tall, narrow vertical interconnects to increase die thickness while maintaining fine pitch. Thicker die in electronic devices can have better thermal performance. By increasing the height of vertical interconnects, the improved thermal performance of thicker die can be realized in electronic devices. Arranging tall vertical interconnects in a configuration with fine pitch can also result in good input/output performance.

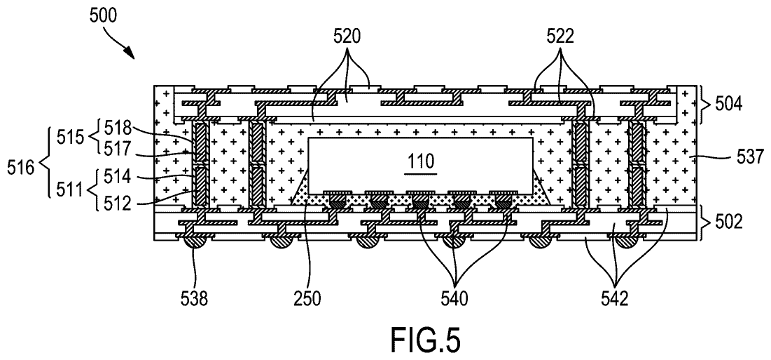

Referring now to FIG. 5, a cross-sectional view of example electronic device 500 is shown. In the example of FIG. 5, electronic device 500 can comprise electronic component 110, vertical interconnects 516, substrate 502, and substrate 504. Electronic device 500 can comprise structures and manufacturing techniques similar to or the same as electronic device 100 (of FIG. 1). In some examples, electronic device 500 can comprise encapsulant 537 and underfill 250. Substrate 502 can include conductive structure 540 and dielectric structure 542. Substrate 504 can include conductive structure 520 and dielectric structure 522. External interconnects 538 can be coupled to conductive structure 540, in some examples.

Vertical interconnects 516 can comprise interconnect structures 511 and 515. Interconnect structures 511 and 515 can comprise narrow pillars, vias, posts, pins, or other narrow interconnects. In some examples, interconnect structures 511 can comprise metallic core structure 512 with fusible material 514 surrounding the metallic core structure 512, and interconnect structures 515 can comprise metallic core structure 517 with fusible material 518 surrounding the metallic core structure 517. In some examples, interconnect structures 511 and 515 can comprise generally cylindrical pins completely or partially surrounded by fusible material.

In various examples, interconnect structure 511 can be coupled between interconnect structure 515 and to substrate 502. Core structures 512 and 517 can each comprise an inner core including metal (e.g., copper or other metals) or alloys with a flowable material 514 disposed around the inner core. In some examples, core structures 512, 517 can each be a narrow interconnect, with each of, core structure 512 and, core structure 517 having a height to width ratio between approximately 2:1 and approximately 20:1, approximately 3:1 and approximately 10:1, or approximately 3:1 and 5:1. Core structure 512 can be coupled to the core structure 517 of interconnect structure 515 by fusible material 514 and/or fusible material 518. In some examples, core structure 512 or core structure 517 of interconnect structures 511 and 515 can comprise a metallic core ball. In some examples, the core structures of interconnect structures 511 or 515 can be mixed with one being a metallic core ball and the other being a metallic core pin. In some examples, each of interconnect structure 511 and interconnect structure 515 can have a height between approximately 100 μm and approximately 300 μm, or between approximately 150 μm and approximately 250 μm.

In some examples, substrate 502 can be electrically coupled to substrate 504 through vertical interconnects 516. Vertical interconnects 516 can be arranged with a fine pitch while supporting increased height of vertical interconnects 516. The thickness of electronic component 110 can be increased, as the volume between substrate 504 and substrate 502 is increased by increasing the height of vertical interconnect 516. In some examples, the height of electronic component 110 can approach the height of vertical interconnect structure 516.

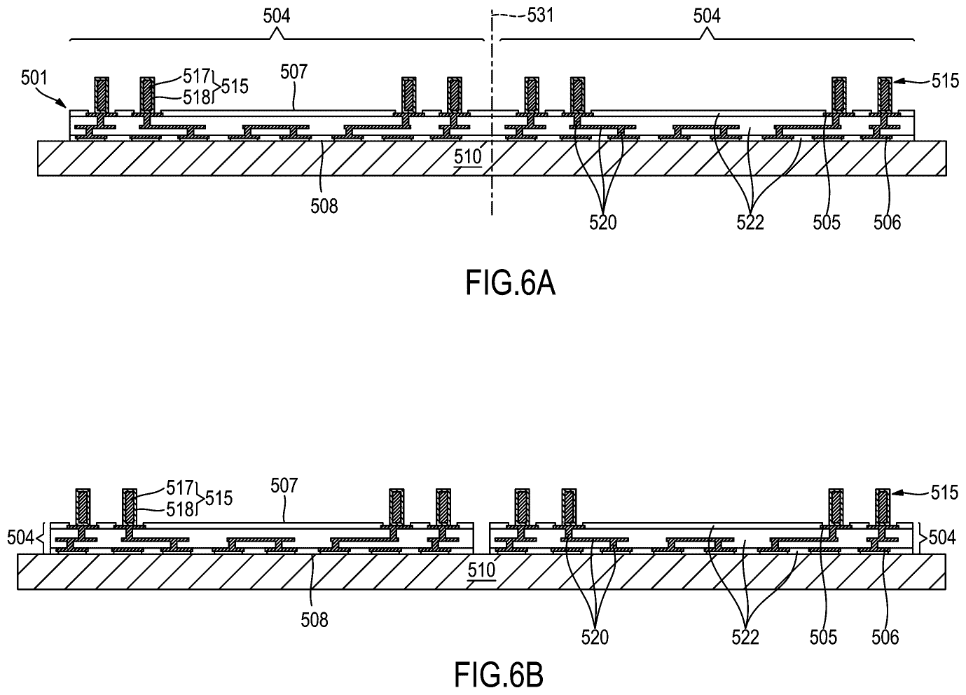

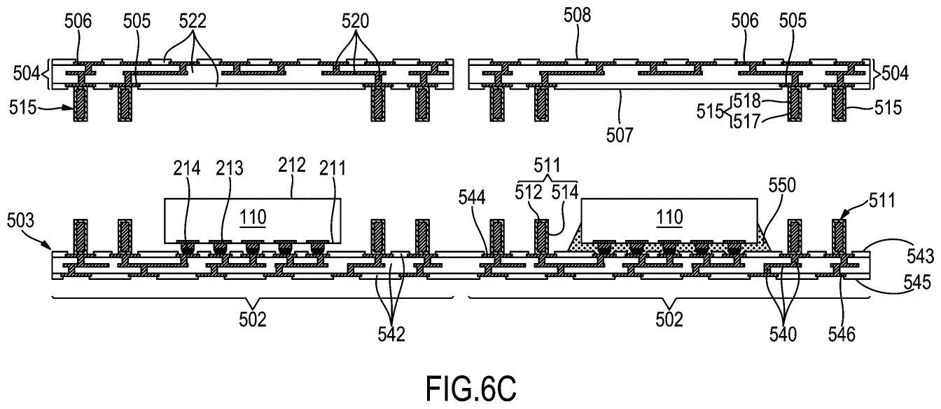

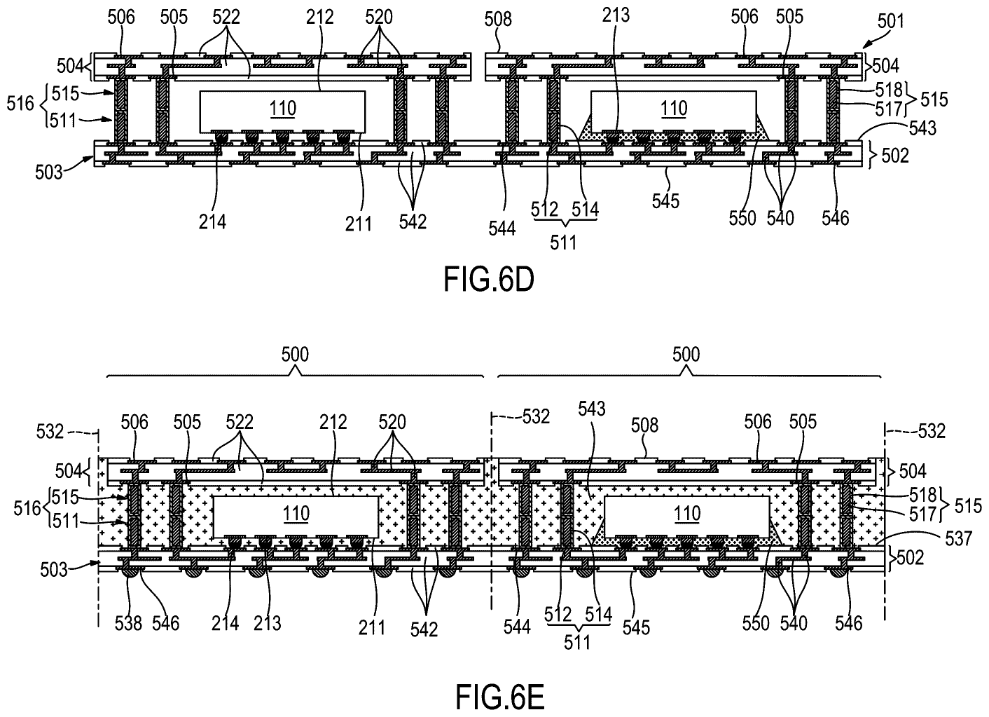

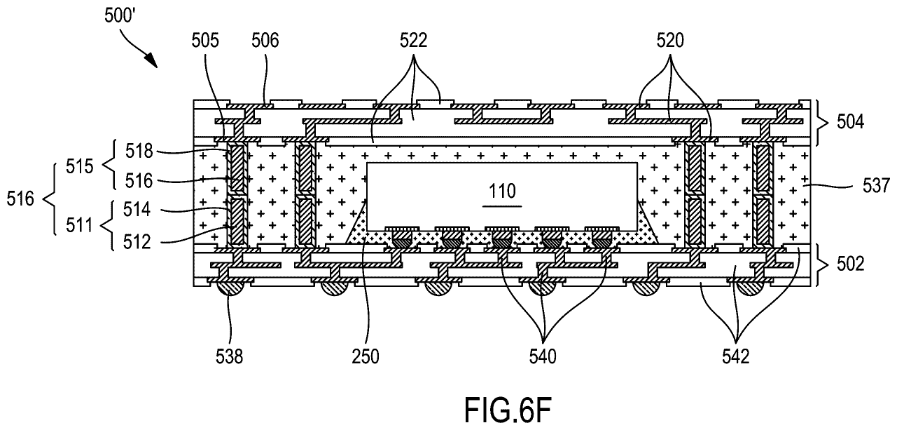

Referring now to FIGS. 6A-6E, an example method of making electronic device 500 is shown, in accordance with various examples. FIG. 6A shows electronic device 500 at an early stage of manufacture. In the example of FIG. 6A, substrates 504 can be provided. In some examples, substrates 504 can be formed integrally together or coupled together as a larger wafer, panel, or workpiece in the form of substrate strip 501. Saw street 531 can separate adjacent substrates 504 in substrate strip 501. Substrates 504 can be coupled to carrier 510. Carrier 510 can comprise structures and techniques similar to or the same as those of carrier 210 (of FIG. 2A). In some embodiments, substrates 504 can be provided as singulated, discrete substrates that are then coupled to carrier 210.

In accordance with various embodiments, substrate 504 can include inner side 507 and outer side 508 opposite inner side 507. Substrate 504 can comprise dielectric structure 522 and conductive structure 520. Conductive structure 520 and dielectric structure 522 of substrate 504 can comprise structures and manufacturing techniques similar to or the same as those of conductive structure 200 and dielectric structure 202, respectively, of substrate 104. Conductive structure 520 can be exposed at inner side 507 and outer side 508 of substrate 504. Conductive structure 522 can comprise inner terminals 505 provided along inner side 507 of substrate 504, and outer terminals 506 provided along outer side 508 of substrate 504. In some examples, inner terminals 505 and outer terminals 506 can comprise or be referred to as pads, lands, or UBM. Layers and elements of conductive structure 520 can electrically couple inner terminals 505 with outer terminals 506.

In some examples, elements, features, materials, or manufacturing methods of substrate 504 can be similar to or the same as those of substrate 104. Substrate 504 can comprise a core or be coreless. In some examples, substrate 504 can comprise or be referred to as a pre-formed or laminate substrate, as previously described. In some examples, substrate 504 can comprise or be referred to as an RDL or build-up substrate, as previously described.

In accordance with various examples, interconnect structures 515 can be coupled to inner terminals 505 of substrate 504. Interconnect structure 515 can comprise metallic core structure 517 and fusible material 518. Metallic core structure 517 and fusible material 518 can comprise structures and techniques similar to or the same as those of core structures 112 and fusible material 114, respectively, of FIG. 1. Interconnect structures 115 can be coupled to substrate 504 by applying a thermocompression, reflow, or laser assisted bonding process in some examples. Fusible material 518 can be coupled to inner terminal 505 and to metallic core structure 517.

FIG. 6B shows electronic device 500 at a later stage of manufacture, in accordance with various examples. In the example of FIG. 6B, individual substrates 504 can be singulated or cut through saw street 531. During the singulation process, a sawing tool (e.g., diamond blade wheel or laser beam) can cut through substrate strip 501 to separate individual substrates 504 from one another. Individual substrates 504 can be used for further processing, as described in further detail below. In some examples substrate strip 501 can remain intact until a later singulation is performed to separate electronic devices 500 from one another (FIG. 6E).

FIG. 6C shows electronic device 500 at a later stage of manufacture, in accordance with various examples. In the example of FIG. 6C, substrate 504 can be provided over substrate 502. In some examples, substrates 502 can be formed integrally together or coupled together as a larger wafer, panel, or workpiece in the form of substrate strip 503. In some examples, substrate strip 503 can be provided over a carrier, similar to carrier 510. In some embodiments, substrates 502 can be provided as singulated, discrete substrates that are then coupled to a carrier.

In accordance with various embodiments, substrate 502 can include inner side 543 and outer side 545 opposite inner side 543. Substrate 502 can comprise dielectric structure 542 and conductive structure 540. Conductive structure 540 and dielectric structure 542 of substrate 502 can comprise structures and manufacturing techniques similar to or the same as those of conductive structure 200 and dielectric structure 202, respectively, of substrate 104. Conductive structure 540 can be exposed at inner side 543 and outer side 545 of substrate 502. Conductive structure 542 can comprise inner terminals 544 provided along inner side 543 of substrate 502, and outer terminals 546 provided along outer side 545 of substrate 502. In some examples, inner terminals 544 and outer terminals 546 can comprise or be referred to as pads, lands, or UBM. Layers and elements of conductive structure 540 can electrically couple inner terminals 544 with outer terminals 546.

In some examples, elements, features, materials, or manufacturing methods of substrate 502 can be similar to or the same as those of substrate 104. Substrate 502 can comprise a core or be coreless. In some examples, substrate 502 can comprise or be referred to as a pre-formed or laminate substrate, as previously described. In some examples, substrate 502 can comprise or be referred to as an RDL or build-up substrate, as previously described.

One or more electronic component(s) 110, as previously described, can be provided over inner side 543 of substrate 502. Connectors 214 can couple contact pads 213 of electronic component 110 to inner terminals 544 of substrate 502. A thermocompression, reflow, or laser assisted bonding process can be performed in some examples to couple electronic component(s) 110 to substrate 502.

In accordance with various examples, interconnect structures 511 provided over inner side 543 of substrate 502. interconnect structures 511 can be coupled to conductive structure 542 (e.g., to inner terminals 544) and can be provided around one or more lateral sides of electronic component 110. In some examples, interconnect structures 511 can be coupled to a perimeter region of substrate 502 and electronic component 110 can be coupled to a central region of substrate 502. For example, interconnect structures 511 can be located laterally between the lateral side of substrate 502 and the electronic component 110. Fusible material 514 of interconnect structure 511 can be coupled to core structure 512 of interconnect structure 511 and inner terminal 544 of substrate 502.

In some examples, an underfill 550 can be provided between front side 211 of electronic component 110 and inner side 543 of substrate 502. Underfill 550 can be provided before or after placement of electronic component 110 on substrate 502. Underfill 550 can include a liquid molding compound (LMC), a capillary underfill (CUF), a molded underfill (MUF), a nonconductive paste (NCP), or other suitable materials. In some examples, underfill 550 can be applied to electronic component 110 by dispensing or printing.

Substrate 504 can be aligned over substrate 502 in some examples. Inner terminals 505 of substrate 504 can be aligned over inner terminals 544 of substrate 502. Interconnect structures 515 can be aligned over interconnect structures 511.

FIG. 6D shows electronic device 500 at a later stage of manufacture, in accordance with various examples. In the example of FIG. 6D, vertical interconnects 516 can be provided or formed by coupling interconnect structure 511 to interconnect structure 515. In the example of FIG. 6D, both interconnect structures 511 and 515 are depicted as pins coupled together by fusible material; however, in some examples, interconnect structure 511 or interconnect structure 515 could comprise a core ball (e.g., spherical) structure and the other of interconnect structure 511 or interconnect structure 515 could comprise a core pin (e.g., cylindrical) structure.

In some examples, a thermocompression, reflow, or laser assisted bonding process can be performed to couple interconnect structure 511 to interconnect structure 515. Aligned interconnect structures 511 and 515 can be coupled together by fusible material 514 and/or fusible material 518. In the example of FIG. 6D, vertical interconnect 516 can comprise metallic core pins (i.e., interconnect structures 511 and 515) stacked vertically and coupled together in response to being urged towards one another. In some examples, heat can be applied to flow fusible material while interconnect structures 511 and 515 are in contact or in close proximity to one another. Substrate 504 can be disposed over and spaced apart from back side 212 of electronic component 110. The height of vertical interconnect structures 516 can be greater than the thickness of electronic component 110.

FIG. 6E shows electronic device 500 at a later stage of manufacture, in accordance with various examples. In the example of FIG. 6E, encapsulant 537 can be provided between substrate 504 and substrate 502.

In various examples, encapsulant 537 can comprise structures and manufacturing techniques similar to or the same as those of encapsulant 137 (of FIG. 2G). Encapsulant 537 can be disposed around sidewalls of vertical interconnects 516, underfill 550, and electronic component 110. In some examples, encapsulant 537 can serve as underfill and can be located between front side 211 of electronic component 110 and inner side 453 of substrate 502. Encapsulant 537 can be disposed over back side 212 of electronic component 110. Encapsulant 537 can extend into or can fill a gap between adjacent substrates 504.

In some examples, external interconnects 538 can be provided over outer side 545 of substrate 502. External interconnects 534 can be coupled to outer terminals 546 of conductive structure 540. External interconnects 538 can comprise structures and manufacturing techniques similar to or the same as external interconnects 138 (of FIG. 2I).

In the example of FIG. 6E, singulation can also be performed. In some examples, singulation can be performed after providing external interconnects 538. In various examples, singulation can be performed by sawing or otherwise cutting through saw streets, for example indicated by lines 532, disposed around a perimeter of electronic devices 500, thereby separating individual electronic devices 500 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate strip 503 and encapsulant 537. In some examples, after singulation, encapsulant 537 can be coplanar with the lateral sides of substrate 502 and can surround the lateral sides of substrate 504. In some examples, saw streets 532 may be configured such that encapsulant 537 is removed from the lateral sides of substrate 504 during singulation. In such examples, encapsulant 537 can be coplanar with the lateral sides of substrate 502 and the lateral sides of substrate 504.

In some examples, after singulation, vertical interconnects 516 can be located in an edge region of electronic device 500, for example at edge regions of substrates 502 and 504. For example, vertical interconnects 516 can be between electronic components 110 and the lateral sides of substrate 502 and/or between electronic components 110 and the lateral sides of substrate 504.

Referring now to FIG. 6F, an electronic device 500′ is shown. Electronic device 500′ can be similar to electronic device 500, but with encapsulant 537 coplanar with the lateral sides of substrate 502 and the lateral sides of substrate 504. Elements, features, materials, or manufacturing methods of electronic device 500′ can be similar to or the same as those of electronic device 500, but in some examples, can be substrates 504, having vertical interconnects 515 on inner side 507, can be disposed over substrates 502 in strip form. For example, substrate strip 501, as shown FIG. 6A, can be disposed over substrates 502, without performing singulation through saw streets 531 (FIG. 6A). In this regard, the singulation of FIG. 6E can be performed through substrate strip 501, encapsulant 537, and substrate strip 503. After singulation, encapsulant 537 can be coplanar with the lateral sides of substrate 502 and the lateral sides of substrate 504.

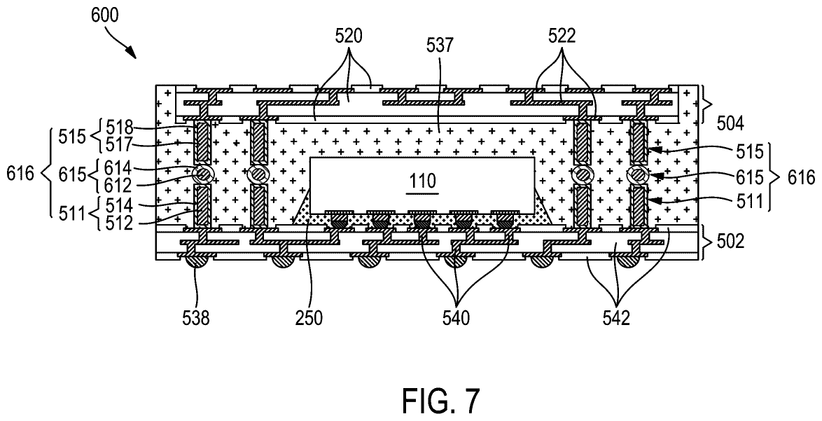

FIG. 7 shows an example electronic device 600, in accordance with various examples. Electronic device 600 can comprise structures and manufacturing techniques similar to or the same as those of electronic device 500 of FIG. 5. Electronic device 600 can include vertical interconnect 616. Vertical interconnect 616 can include interconnect structure 511, as previously described, interconnect structure 515, as previously described, and interconnect structure 615. Interconnect structure 615 can comprise metallic core structure 612 and fusible material 614 around metallic core structure 612. Metallic core structure 612 can comprise a spherical, rounded, or elliptical geometry in various examples. In that regard, some examples of interconnect structure 615 can comprise a copper core ball or other metallic core ball. Interconnect structure 615 (e.g., a metallic core ball) can be coupled to interconnect structure 515 and interconnect structure 511. Although interconnect structures 615 are shown having metallic core balls, in some examples, solder balls can be used as interconnect structures 615 (e.g., interconnect structures 615 can be devoid of metallic core structure 612). In some examples, interconnect structures 615 can be coupled to interconnect structures 515 prior to disposing substrate 504 over substrate 502. In other examples, interconnect structures 615 can be coupled to interconnect structures 511 prior to disposing substrate 504 over substrate 502. Once substrate 504 is disposed over substrate 502, a thermocompression, reflow, or laser assisted bonding process can be used to couple interconnect structure 615 to interconnect structure 511 and/or to interconnect structures 515. Vertical interconnect 716 can couple substrate 504 to substrate 502.

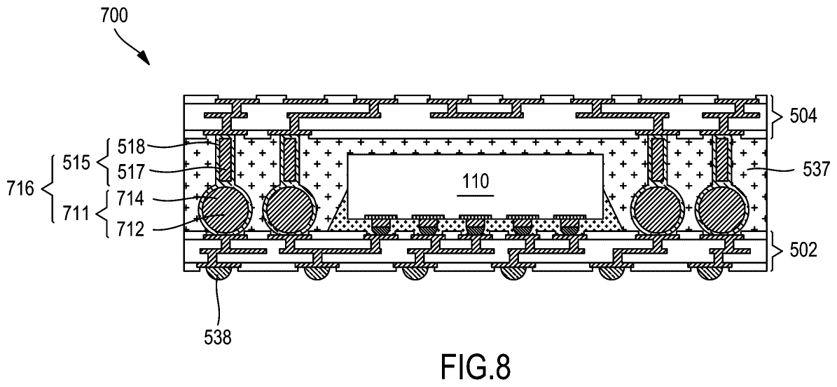

FIG. 8 shows an example electronic device 700, in accordance with various examples. Electronic device 700 can comprise structures and manufacturing techniques similar to or the same as those of electronic device 500 of FIG. 5. Electronic device 700 can include vertical interconnect 716. Vertical interconnect 716 can include interconnect structure 515, as previously described, and interconnect structure 711 comprising metallic core structure 712 and fusible material 714 around metallic core structure 712. Metallic core structure 712 can comprise a spherical, rounded, or elliptical geometry in various examples. In that regard, some examples of interconnect structure 711 can comprise a copper core ball or other metallic core ball. Vertical interconnect 716 can couple substrate 504 to substrate 502. Interconnect structure 711 (e.g., a metallic core ball) can be coupled to substrate 502 in the example of FIG. 8 with interconnect structure 515 (e.g., a metallic core pin) coupled to substrate 504. In some examples, an interconnect structure 515 comprising a metallic core ball surrounded by fusible material 518 can be coupled to substrate 504 and a metallic core pin interconnect structure 511, as previously described, can be coupled to substrate 502. In some examples, both interconnect structures 711 and 515 can comprise metallic core balls. In some examples, interconnect structure 711 can have a height between approximately 100 μm and approximately 300 μm, or between approximately 150 μm and approximately 250 μm.

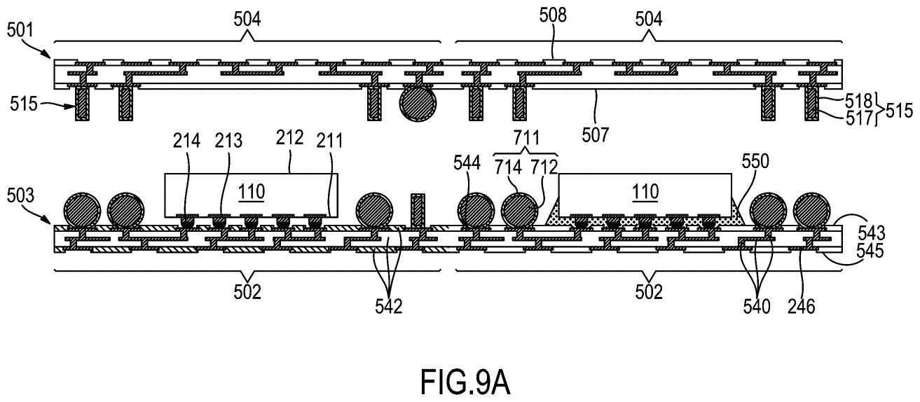

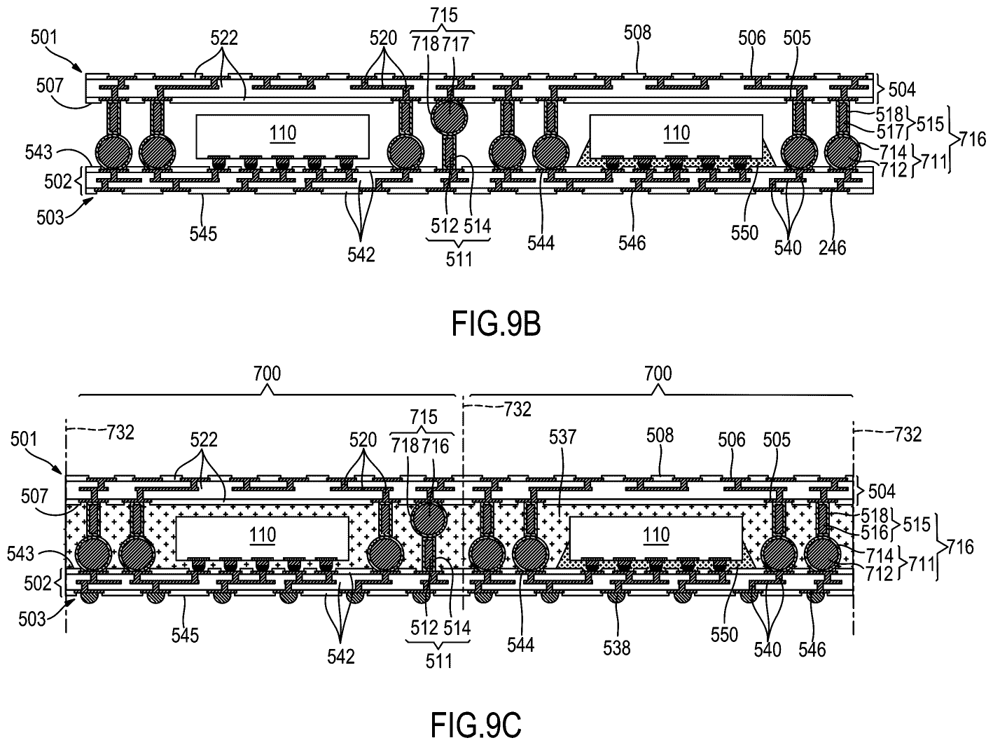

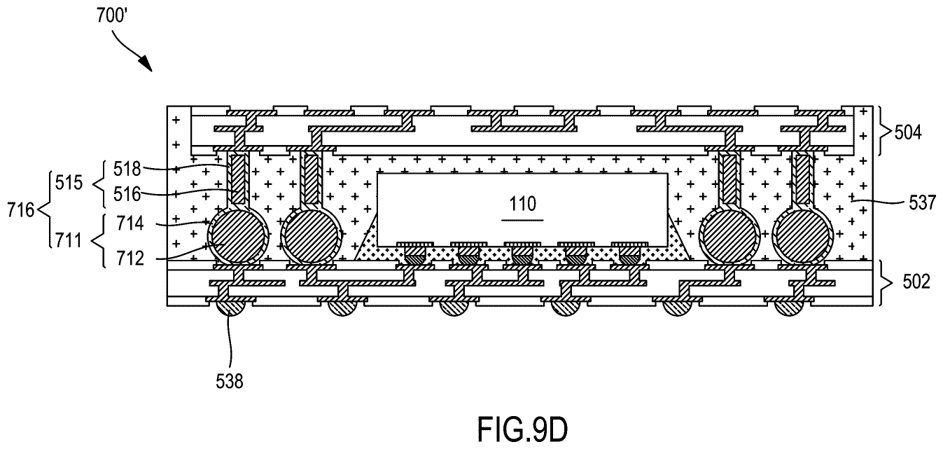

FIGS. 9A-9C show an example method of making electronic device 700, according to various examples. The example of FIGS. 9A-9C can continue from the step shown in FIG. 6A. For example, FIG. 9A shows electronic device 700 at a stage of manufacture after the step shown in FIG. 6A.

In the example of FIG. 9A, substrate strip 503 can be provided with interconnect structure 711 (e.g., metallic core balls) coupled to inner terminals 544 of substrates 502. Interconnect structures 711 can comprise structures and techniques similar to those of interconnect structures 511. In the example of FIG. 9A, interconnect structures 711 comprise metallic core balls, and in the example of FIG. 6C interconnect structures 511 comprise metallic core pins. Interconnect structures 711 can be coupled to substrate 502 around the lateral sides of electronic component 110. Fusible material 714 of interconnect structures 711 can be coupled to inner terminal 544 and to metallic core structure 712 of interconnect structure 711.

Electronic components 110, as previously described, can be coupled to substrates 502 between interconnect structures 711. Substrates 504 can be over substrates 502 with inner terminals 505 of substrate 504 aligned over inner terminals 544 of substrate 502. In some examples, substrates 504 can be disposed over substrates 502 as part of substrate strip 501. In some examples, substrates 504 can be singulated prior to being disposed over substrates 502, similar to substrates 504 in FIG. 6C. Interconnect structures 515 can be aligned over interconnect structures 711. For example, pins coupled to substrates 504 are aligned over balls coupled to substrates 502.

FIG. 9B shows electronic device 700 at a later stage of manufacture, in accordance with various examples. In the example of FIG. 9B, vertical interconnects 516 can be provided or formed by coupling interconnect structure 711 to interconnect structure 515 and/or by coupling interconnect structure 715 to interconnect structure 511. Vertical interconnects 716 can comprise structures and techniques similar to those of vertical interconnects 516. In the example of FIG. 9B, vertical interconnects 716 comprise metallic core balls coupled to metallic core pins.

FIG. 9C shows electronic device 700 at a later stage of manufacture, in accordance with various examples. In the example of FIG. 9C, encapsulant 537, as previously described, can be provided between substrates 504 and substrates 502.

In various examples, encapsulant 537 can be disposed around sidewalls of vertical interconnects 716. Encapsulant 537 can be disposed between electronic component 110 and interconnect structures 711/511 and between electronic component 110 and interconnect structures 515/715. Encapsulant 537 can extend between and/or contact inner side 507 of substrate 504 and inner side 543 of substrate 502.

In some examples, external interconnects 538 can be provided over outer side 545 of substrate 502. External interconnects 534 can be coupled to outer terminals 546 of conductive structure 540. External interconnects 538 can comprise structures and manufacturing techniques similar to or the same as external interconnects 138 (of FIG. 2I).

In the example of FIG. 9C, singulation can also be performed. In some examples, singulation can be performed after providing external interconnects 538. In various examples, singulation can be performed by sawing or otherwise cutting through saw streets, for example indicated by lines 732, disposed around a perimeter of electronic devices 700, thereby separating individual electronic devices 700 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate strip 501, substrate strip 503, and encapsulant 537. In some examples, after singulation, encapsulant 537 can be coplanar with the lateral sides of substrate 502 and the lateral sides of substrate 504.

In some examples, after singulation, vertical interconnects 716 can be located in an edge region of electronic device 700, for example at edge regions of substrates 502 and 504. For example, vertical interconnects 716 can be between electronic components 110 and the lateral sides of substrate 702 and/or between electronic components 110 and the lateral sides of substrate 504.

Referring now to FIG. 9D, an electronic device 700′ is shown. Electronic device 700′ can be similar to electronic device 700, but with encapsulant 537 surrounding the lateral sides of substrate 504. Elements, features, materials, or manufacturing methods of electronic device 700′ can be similar to or the same as those of electronic device 700, but in some examples, can be substrates 504, having vertical interconnects 515/715 on inner side 507, can be disposed over substrates 502, as discrete, singulated substrates. For example, substrates 504, as shown FIG. 6C, can be disposed over substrates 502, after performing singulation through saw streets 531 (FIG. 6A). In this regard, the singulation of FIG. 9C can be performed through encapsulant 537 and substrate strip 503. After singulation, encapsulant 537 can be coplanar with the lateral sides of substrate 502 and can surround the lateral sides of substrate 504.

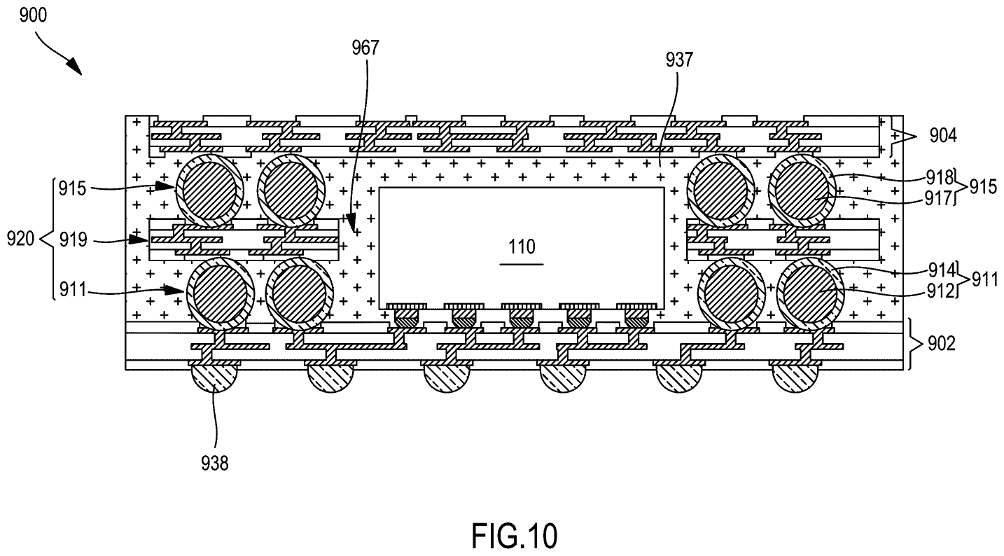

Referring now to FIG. 10, example electronic device 900 is shown in cross section, in accordance with various examples. Example electronic device 900 can comprise structures and manufacturing techniques similar to or the same as those of electronic device 100, electronic device 500, electronic device 700, or any other electronic device described herein.

In the example of FIG. 10, electronic device 900 comprises vertical interconnect 920 coupled to substrate 902 and to substrate 904. Vertical interconnect 920 can comprise interconnect structure 911, intermediate substrate 919, and interconnect structure 915. Electronic component 110 can be in electronic communication with substrate 904 through substrate 902 and vertical interconnect 920. External interconnects 938 can be coupled to substrate 902 opposite electronic component 110 and opposite vertical interconnect 920.

Interconnect structures 911 and 915 can comprise pillars, vias, posts, pins, balls, or other interconnect structures. In some examples, interconnect structures 911 can comprise metallic core structure 912 with fusible material 914 surrounding the metallic core structure, and interconnect structures 915 can comprise metallic core structure 917 with fusible material 918 surrounding the metallic core structure. In some examples, interconnect structures 911 and/or interconnect structures 915 can comprise copper core balls or other metallic core balls completely or partially surrounded by fusible material. In some examples, interconnect structures 911 and/or interconnect structures 915 can comprise copper core pins or other metallic core pins completely or partially surrounded by fusible material. In some examples, the core structures of interconnect structures 911 or 915 can be mixed with one being a metallic core ball and the other being a metallic core pin or solder ball. In some examples, vertical interconnects 920 can have a height between 300 μm and 580 μm, between 350 μm and 500 μm, or between 380 μm and 450 μm. In some examples, interconnect structures 911 and interconnect structures 915 can each have a height between approximately 50 μm and approximately 250 μm, between approximately 80 μm and approximately 150 μm, between approximately 100 μm and approximately 150 μm, or between approximately 80 μm and approximately 125 μm. In some examples, intermediate substrate can have thickness between approximately 100 μm and approximately 400 μm, between approximately 100 μm and approximately 350 μm, between approximately 130 μm and approximately 250 μm, or between approximately 130 μm and approximately 230 μm.

In various examples, interconnect structure 911 can be coupled to intermedial substrate 919 and to substrate 902, and interconnect structure 915 can be coupled to intermedial substrate 919 and to substrate 904. Core structures 912, 917 can comprise metallic balls, metallic pins, metallic pillars, or other conductive structures. Although interconnect structures 911 and 915 are shown having metallic core balls, in some examples, solder balls can be used as interconnect structures 911 or 915. In some examples, core structure 912 and/or core structure 917 can be omitted or can comprise flowable material or solder resulting in interconnect structures 911 or 915 comprising solder or flowable material completely throughout.

Intermediate substrate 919 of vertical interconnects 920 can include opening 967. Electronic component 110 can be located in opening 967. In accordance with various examples, vertical interconnect 920 including intermediate substrate 919 can be configured with a fine pitch (e.g., smaller diameter interconnects 911, 915,) while supporting an increased overall height of vertical interconnect 920. Taller vertical interconnect 920 allows the thickness of electronic component 110 to be increased, as the volume between substrate 904 and substrate 902 is increased by increasing the height of vertical interconnect 920. In some examples, the height of electronic component 110 can approach the height of vertical interconnect 920. Thicker electronic components can result in improved thermal performance in some examples.

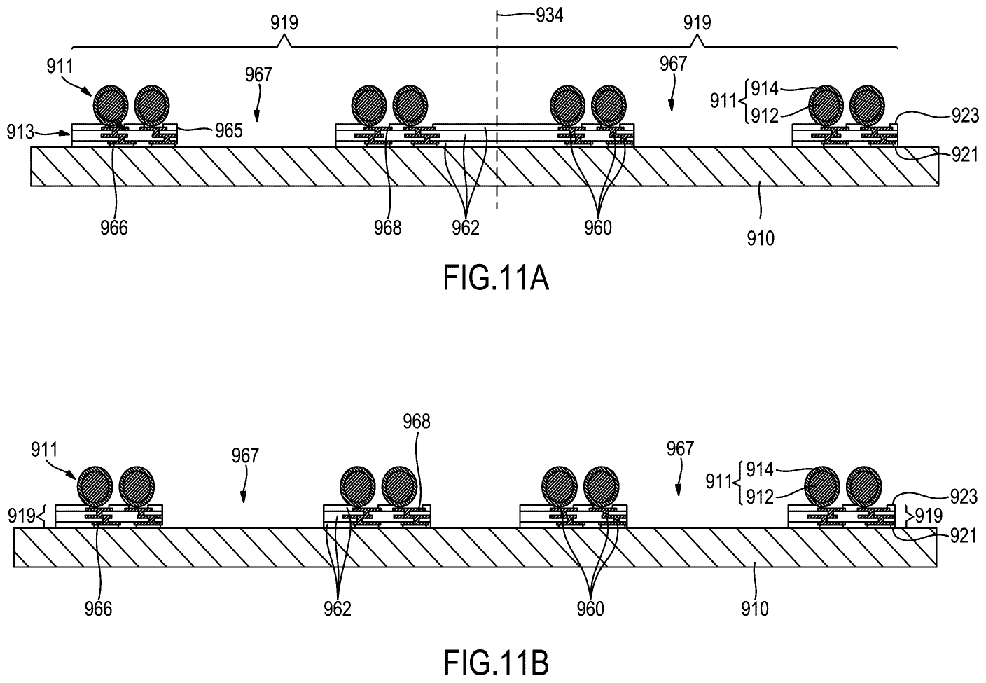

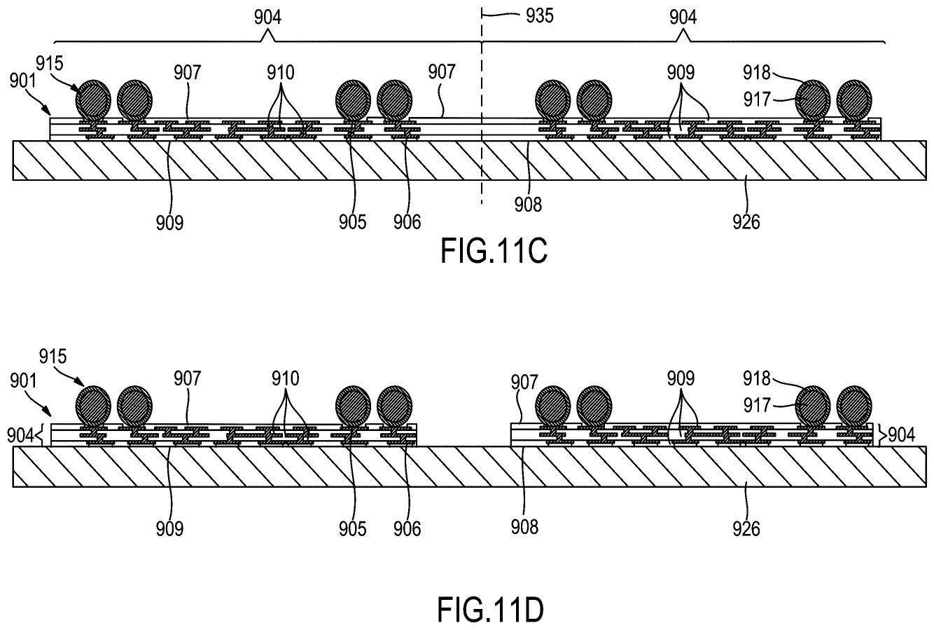

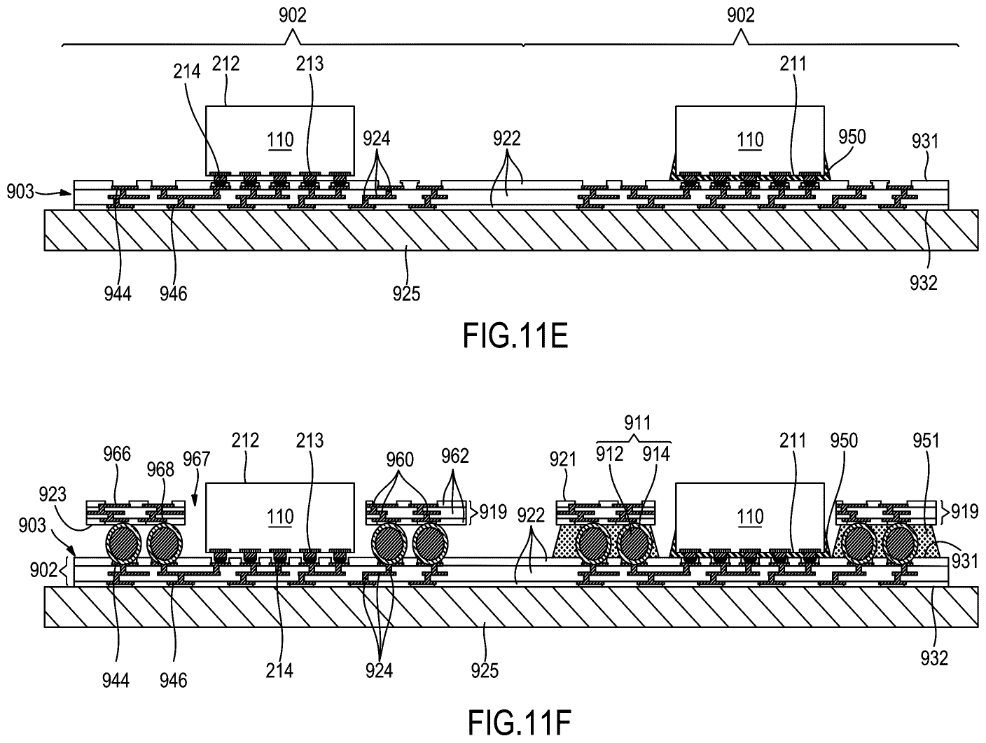

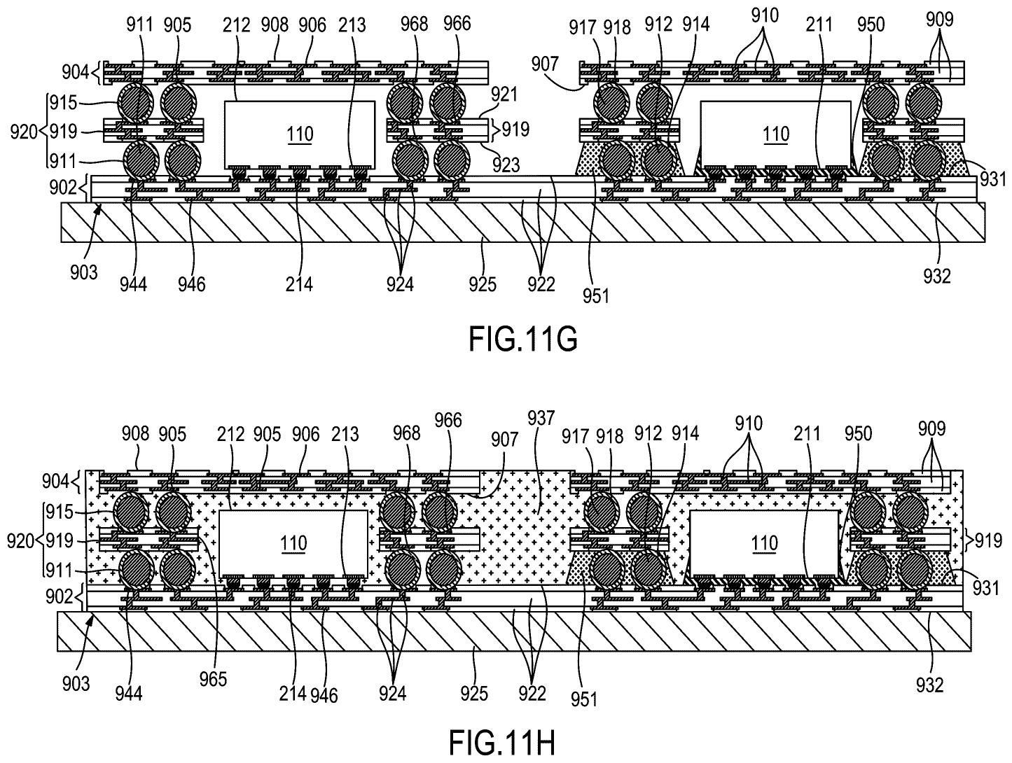

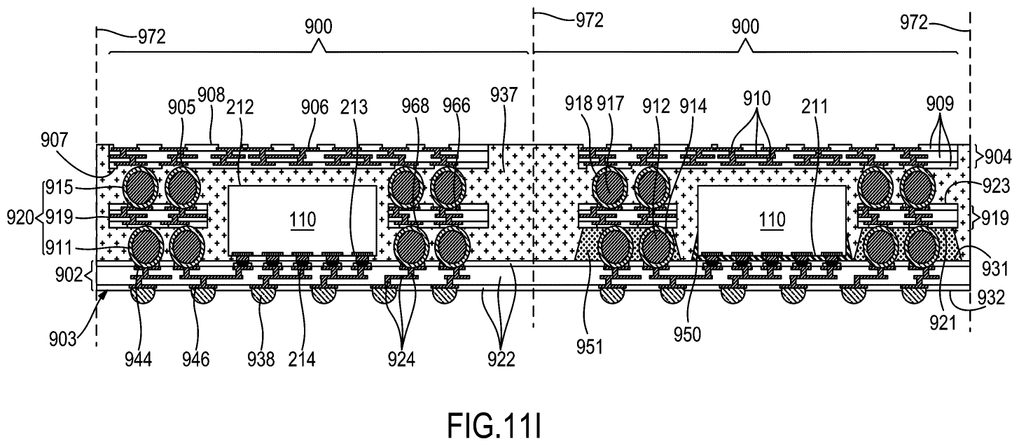

FIGS. 11A-11I illustrate an example method of manufacturing an electronic device, such as electronic device 900 of FIG. 10, in accordance with various examples. FIG. 11A shows electronic device 900 at an early stage of manufacture. In the example of FIG. 11A, intermediate substrates 919 can be provided. In some examples, intermediate substrates 919 can be formed integrally together or coupled together as a larger wafer, panel, or workpiece in the form of substrate strip 913. Saw street 934 can separate adjacent intermediate substrates 919 in substrate strip 913. In some examples, intermediate substrates 919 can be coupled to carrier 910. Carrier 910 can comprise structures and techniques similar to or the same as those of carrier 210 (of FIG. 2A). In some embodiments, intermediate substrates 919 can be provided as singulated, discrete substrates that are then coupled to carrier 910.

In accordance with various embodiments, intermediate substrates 919 can include inner side 921 and outer side 923 opposite inner side 921. Intermediate substrates 919 can comprise dielectric structure 962 and conductive structure 924. Conductive structure 960 and dielectric structure 962 of intermediate substrate 919 can comprise structures and manufacturing techniques similar to or the same as those of conductive structure 200 and dielectric structure 202, respectively, of substrate 104. Conductive structure 960 can be exposed at inner side 921 and outer side 923 of intermediate substrate 919. Conductive structure 960 can comprise inner terminals 966 provided along inner side 921 of intermediate substrate 919, and outer terminals 968 provided along outer side 923 of intermediate substrate 919. In some examples, inner terminals 966 and outer terminals 968 can comprise or be referred to as pads, lands, or UBM. Layers and elements of conductive structure 960 can electrically couple inner terminals 966 with outer terminals 968.

In some examples, elements, features, materials, or manufacturing methods of intermediate substrate 919 can be similar to or the same as those of substrate 104. Intermediate substrate 919 can comprise a core or be coreless. In some examples, intermediate substrate 919 can comprise or be referred to as a pre-formed or laminate substrate, as previously described. In some examples, intermediate substrate 919 can comprise or be referred to as an RDL or build-up substrate, as previously described.

In accordance with various examples, interconnect structures 911 can be coupled to outer terminals 968 of intermediate substrate 919. Interconnect structure 911 can comprise metallic core structure 912 and fusible material 914. Metallic core structure 912 and fusible material 914 can comprise structures and techniques similar to or the same as those of core structures 112 and fusible material 114, respectively, of FIG. 1. Interconnect structures 911 can be coupled to intermediate substrate 919 by applying a thermocompression, reflow, or laser assisted bonding process in some examples. Fusible material 914 can be coupled to outer terminal 968 and to metallic core structure 912.

In accordance with various examples, intermediate substrate 919 can comprise inner sidewalls 965 defining opening 967. Opening 967 can extend from completely through intermediate substrate 919. For example, opening 967 can extend from inner side 921 to outer side 923 of intermediate substrate 919. Opening 967 can be sized to receive an electronic component 110 (of FIG. 10).

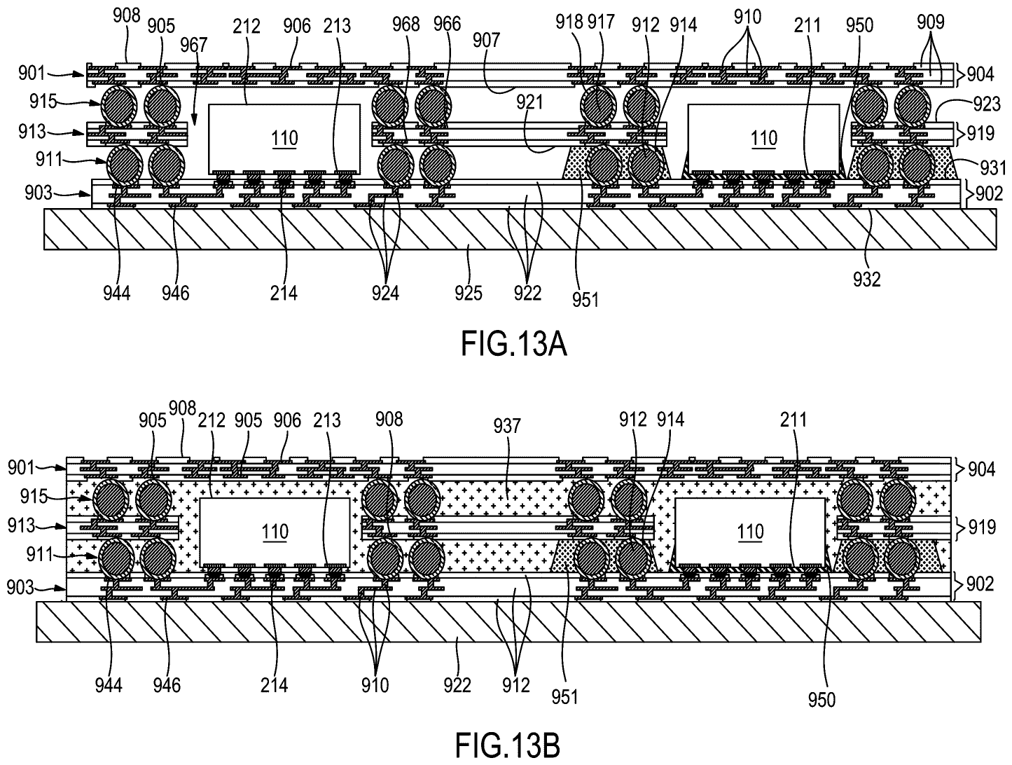

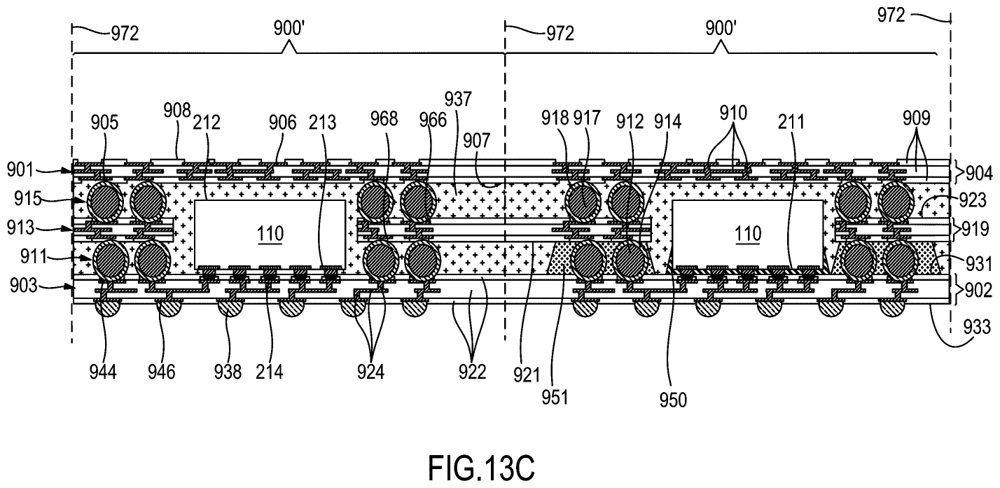

FIG. 11B shows electronic device 900 at a later stage of manufacture, in accordance with various examples. In the example of FIG. 11B, intermediate substrate 919 can be separated by singulating through saw street 934. During the singulation process, a sawing tool (e.g., diamond blade wheel or laser beam) can cut sacrificial connective material coupling adjacent intermediate substrates 919 to separate individual intermediate substrates 919 from one another. In some examples, intermediate substrates 919 can remain coupled to one another in a larger work piece for future processing (as shown later in FIG. 13A).

FIG. 11C shows electronic device 900 at another stage of manufacture, in accordance with various examples. In the example of FIG. 11C substrates 904 can be provided. Substrate 904 can be provided before, during, or after provision of intermediate substrate 919.

In some examples, substrates 904 can be formed integrally together or coupled together as a larger wafer, panel, or workpiece in the form of substrate strip 901. Saw street 935 can separate adjacent substrates 904 in substrate strip 901. In some examples, substrates 904 can be coupled to carrier 926. Carrier 926 can comprise structures and techniques similar to or the same as those of carrier 210 (of FIG. 2A). In some embodiments, substrates 904 can be provided as singulated, discrete substrates that are then coupled to carrier 926.

In accordance with various embodiments, substrates 904 can include inner side 907 and outer side 908 opposite inner side 907. Substrates 904 can comprise dielectric structure 909 and conductive structure 960. Conductive structure 960 and dielectric structure 909 of substrate 904 can comprise structures and manufacturing techniques similar to or the same as those of conductive structure 200 and dielectric structure 202, respectively, of substrate 104. Conductive structure 960 can be exposed at inner side 907 and outer side 908 of substrate 904. Conductive structure 960 can comprise inner terminals 905 provided along inner side 907 of substrate 904, and outer terminals 906 provided along outer side 908 of substrate 904. In some examples, inner terminals 905 and outer terminals 906 can comprise or be referred to as pads, lands, or UBM. Layers and elements of conductive structure 960 can electrically couple inner terminals 905 with outer terminals 906.

In some examples, elements, features, materials, or manufacturing methods of substrate 904 can be similar to or the same as those of substrate 104. Substrate 904 can comprise a core or be coreless. In some examples, substrate 904 can comprise or be referred to as a pre-formed or laminate substrate, as previously described. In some examples, substrate 904 can comprise or be referred to as an RDL or build-up substrate, as previously described.

In accordance with various examples, interconnect structures 915 can be coupled to inner terminals 905 of substrate 904. Interconnect structure 915 can comprise metallic core structure 917 and fusible material 918. Metallic core structure 917 and fusible material 918 can comprise structures and techniques similar to or the same as those of core structures 112 and fusible material 114, respectively, of FIG. 1. Interconnect structures 915 can be coupled to substrate 904 by applying a thermocompression, reflow, or laser assisted bonding process in some examples. Fusible material 918 can be coupled to inner terminal 905 and to metallic core structure 917.

FIG. 11D shows electronic device 900 at a later stage of manufacture, in accordance with various examples. In the example of FIG. 11D, substrate strip 901 can be singulated through saw street 935. Singulation can be performed using structures and manufacturing techniques described herein. In some examples, singulation can be postponed and substrates 904 can remain coupled to one another in substrate strip 901 for further processing. In such examples singulation can be performed during a later step.

FIG. 11E shows electronic device 900 at a later stage of manufacture, in accordance with various examples. In the example of FIG. 11E, substrates 902 can be provided. In some examples, substrates 902 can be formed integrally together or coupled together as a larger wafer, panel, or workpiece in the form of substrate strip 903. In some examples, substrates 902 can be coupled to carrier 925. Carrier 925 can comprise structures and techniques similar to or the same as those of carrier 210 (of FIG. 2A). In some embodiments, substrates 902 can be provided as singulated, discrete substrates that are then coupled to carrier 925.

In accordance with various embodiments, substrates 902 can include inner side 931 and outer side 932 opposite inner side 931. Substrates 902 can comprise dielectric structure 922 and conductive structure 924. Conductive structure 924 and dielectric structure 922 of substrate 902 can comprise structures and manufacturing techniques similar to or the same as those of conductive structure 200 and dielectric structure 202, respectively, of substrate 104. Conductive structure 924 can be exposed at inner side 931 and outer side 932 of substrate 902. Conductive structure 924 can comprise inner terminals 944 provided along inner side 931 of substrate 902, and outer terminals 946 provided along outer side 932 of substrate 902. In some examples, inner terminals 944 and outer terminals 946 can comprise or be referred to as pads, lands, or UBM. Layers and elements of conductive structure 924 can electrically couple inner terminals 944 with outer terminals 946.

In some examples, elements, features, materials, or manufacturing methods of substrate 902 can be similar to or the same as those of substrate 104. Substrate 902 can comprise a core or be coreless. In some examples, substrate 902 can comprise or be referred to as a pre-formed or laminate substrate, as previously described. In some examples, substrate 902 can comprise or be referred to as an RDL or build-up substrate, as previously described.

Electronic component 110, as previously described, can be coupled to substrate 902 by connectors 214. Connectors 214 can be coupled to inner terminals 944 of conductive structure 924 and contacts 213 of electronic component 110. Thermocompression, reflow, or laser assisted bonding can be performed in some examples to couple electronic components 110 to substrate 902.

In some examples, underfill 950 can be provided between front side 211 of electronic component 110 and inner side 931 of substrate 902. Underfill 950 can be omitted in some examples. In some examples, underfill 950 can be provided before or after placement of electronic component 110 on substrate 902. Underfill 950 can comprise structures and manufacturing techniques similar to or the same as those of underfill 550 or other underfills described herein.

FIG. 11F shows electronic device 900 at a later stage of manufacture, in accordance with various examples. In the example of FIG. 11F, intermediate substrates 919 can be coupled to substrates 902. Electronic component 110 can be located in opening 967 of intermediate substrate 919.

In some examples, intermediate substrates 919 can be aligned over and urged towards substrates 902. Inner terminals 968 of intermediate substrate 919 can be aligned over inner terminals 944 of substrate 902. Interconnect structures 911 can be aligned over inner terminals 944. In some examples, thermocompression, reflow, or laser assisted bonding can be performed to couple flowable material 914 of interconnect structure 911 with inner terminal 944. In some examples, interconnect structure 911 can be coupled to substrate 902 prior to intermediate substrate 919. For example, intermediate substrates 919 can be located over interconnect structures 911 that have been coupled to substrate 902 with exposed inner terminals 968 of intermediate substrate 919 aligned over interconnect structures 911.

In some examples, underfill 951 can be provided between intermediate substrate 919 and substrate 902. Underfill 951 can comprise structures and manufacturing techniques similar to or the same as underfill 950 or other underfills described herein. The height of back side 212 of electronic component 110 above substrate 902 can be greater than or equal to the height inner side 921 of intermediate substrate 919 above substrate 902.

In some examples, interconnect structures 911 can be coupled to substrate 902 and intermediate substrate 919 around the lateral sides of electronic components 110. Interconnect structures 911 can be coupled to a perimeter region of substrate 902, and electronic components 110 can be coupled to a central region of substrate 902. Intermediate substrate 919 can be located laterally adjacent to one, two, three, or four lateral sides of electronic component 110 (e.g., intermediate substrate 919 can surround or extend partially around electronic component 110).

FIG. 11G shows electronic device 900 at a later stage of manufacture, in accordance with various examples. In the example of FIG. 11G, substrates 904 can be coupled to intermediate substrates 919.

In various examples, substrates 904 can be aligned over intermediate substrates 919 and over substrates 902, with intermediate substrates 919 located between substrates 904 and substrates 902. Inner terminals 905 of substrate 904 can be aligned over inner terminals 966 of intermediate substrates 919. Interconnect structures 915 can be aligned over and coupled to inner terminals 966 of intermediate substrates 919. For example, thermocompression, reflow, or laser assisted bonding can be performed to couple flowable material 918 of interconnect structure 915 with inner terminal 905. Interconnect structures 915 and 911 can be substantially aligned vertically in some examples, and as depicted in FIG. 11G. In some examples interconnect structure 915 and interconnect structure 911 can be staggered vertically (e.g., laterally offset from one another). In some examples, interconnect structures 915 can be coupled to intermediate substrates 919 prior to substrates 904. For example, substrates 904, without interconnect structures 915 coupled thereto, can be disposed over interconnect structures 915 coupled to inner terminal 964 of intermediate substrate 919, with inner terminals 905 of substrate 904 aligned over interconnect structures 915.

Electronic component 110 can be electrically coupled to conductive structure 960 of substrate 904 through conductive structure 924 of substrate 902 and vertical interconnects 920. Electronic communication across vertical interconnect 920 can be conducted through interconnect structure 911, intermediate substrate 919, and interconnect structure 915.

In some examples, vertical interconnects 920 can extend from substrate 902 to substrate 904. Vertical interconnects 920 can comprise interconnect structure 911, intermediate substrate 919, and interconnect structure 915. Vertical interconnects 920 can have a relatively large height and fine pitch to support a thick electronic component 110. Vertical interconnects 920 can be disposed around the lateral sides of electronic component 110. Electronic component 110 can at least partially fill opening 967 defined by inner side 931 of substrate 902, inner sidewalls 965 of intermediate substrate 919, and inner side 907 of substrate 904.

FIG. 11H shows electronic device 900 at a later stage of manufacture, in accordance with various examples. In the example of FIG. 11H, encapsulant 937 can be provided. Encapsulant 937 can comprise structures and manufacturing techniques similar to or the same as those of encapsulant 137 or other encapsulants described herein. In some examples, encapsulant 937 can be disposed around the lateral sides of substrate 904 and of intermediate substrate 919. Encapsulant 937 can be disposed between substrate 902 and intermediate substrate 919. Encapsulant 937 can be disposed between substrate 904 and intermediate substrate 919. Encapsulant 937 can be disposed between internal sidewall 965 of intermediate substrate 919 and the lateral side of electronic component 110. Encapsulant 937 can be disposed between electronic component 110 and inner side 931 of substrate 902, in some examples. Encapsulant 937 can surround and/or contact connectors 214, in some examples.

In various examples, encapsulant 937 can be disposed around the lateral sides of interconnect structure 915 and interconnect structure 911. Metallic core structures and flowable material of interconnect structure 915 and 911 can be completely covered by encapsulant 937 in some examples. Solder bonds between interconnect structure 915 and inner terminal 905 of substrate 904; between interconnect structure 915 and inner terminal 964 of intermediate substrate 919; between interconnect structure 911 and outer terminal 968 of intermediate substrate 919; and between interconnect structure 911 and inner terminal 944 of substrate 902 can be covered by encapsulant 937.

FIG. 11I shows electronic device 900 at a later stage of manufacture, in accordance with various examples. In the example of FIG. 11I, external interconnects 938 can be provided.

In some examples, external interconnects 938 can be located on outer side 932 of substrate 902. External interconnects 938 can be disposed on and coupled to outer terminals 946. External interconnects 938 can comprise structures and manufacturing techniques similar to or the same as those of external interconnects 138 or other external interconnects described herein.

In the example of FIG. 11I, singulation can also be performed. In some examples, singulation can be performed after providing external interconnects 938. In various examples, singulation can be performed by sawing or otherwise cutting through saw streets, for example indicated by lines 972, disposed around a perimeter of electronic devices 900, thereby separating individual electronic devices 900 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate strip 903 and encapsulant 937. In some examples, after singulation, encapsulant 937 can be coplanar with the lateral sides of substrate 902 and can surround the lateral sides of substrate 904 and/or the lateral sides of intermediate substrate 919. In some examples, saw streets 972 may be configured such that encapsulant 937 is removed from the lateral sides of substrate 504 and/or the lateral sides of intermediate substrate 919 during singulation. In such examples, encapsulant 937 can be coplanar with the lateral sides of substrate 902 and the lateral sides of substrate 904 and/or with the lateral sides of intermediate substrate 919.

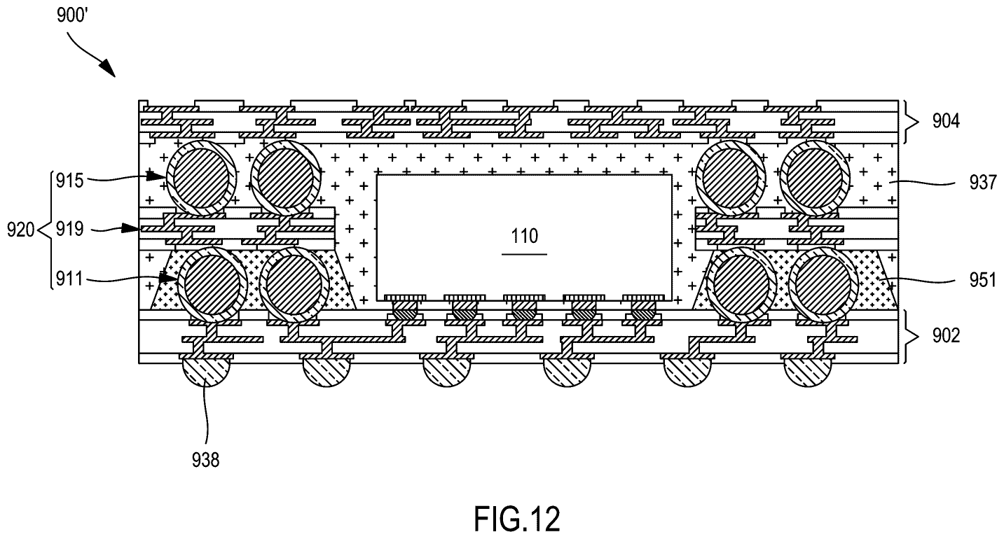

Referring now to FIG. 12, example electronic device 900′ is shown in cross section, in accordance with various examples. Example electronic device 900′ can comprise structures and manufacturing techniques similar to or the same as those of electronic device 900 or other electronic devices described herein. In the example of FIG. 12, encapsulant 937 can be coplanar with the lateral sides of substrate 902, the lateral sides of substrate 904 and with the lateral sides of intermediate substrate 919.

FIGS. 13A-13C show an example method of making electronic device 900′, according to various examples. The example of FIGS. 13A-13C can continue from one or more of the steps shown in FIGS. 11A, 11C, and 11E-11F. In the example of FIG. 13A, substrate strip 913, having interconnect structures 911 coupled to outer terminals 968 of intermediate substrates 919 is provided over substrates 902 and/or substrate strip 903. Fusible material 914 of interconnect structures 911 can be coupled to inner terminal 944, outer terminals 968, and to metallic core structure 912 of interconnect structure 911. Substrate strip 901, having interconnect structures 915 coupled to inner terminals 905 of substrates 904 is provided over intermediate substrates 919 and/or substrate strip 903. Fusible material 918 of interconnect structures 915 can be coupled to inner terminal 968, inner terminals 905, and metallic core structure 917 of interconnect structure 915. Electronic components 110, as previously described, can be coupled to substrates 902 between interconnect structures 911 and within openings 967 of intermediate substrate 919.

FIG. 13B shows electronic device 900′ at a later stage of manufacture, in accordance with various examples. In the example of FIG. 13B encapsulant 937, as previously described, can be provided between substrates 904 and intermediate substrates 919 and between intermediate substrates 919 and substrates 902. Encapsulant 937 can be disposed around sidewalls of interconnect structures 911 and 915. Encapsulant 937 can be disposed between electronic component 110 and interconnect structures 911, between electronic component 110 and interconnect structures 915, and between electronic component 110 and intermediate substrate 919.

FIG. 13C shows electronic device 900′ at a later stage of manufacture, in accordance with various examples. In the example of FIG. 13C, external interconnects 938, as previously described, can be provided over outer side 933 of substrate 902. External interconnects 938 can be coupled to outer terminals 946 of conductive structure 924.

In the example of FIG. 13C, singulation can also be performed. In some examples, singulation can be performed after providing external interconnects 938. In various examples, singulation can be performed by sawing or otherwise cutting through saw streets, for example indicated by lines 972, disposed around a perimeter of electronic devices 900′, thereby separating individual electronic devices 900′ from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate strip 901, substrate strip 913, substrate strip 903, and encapsulant 937. In some examples, after singulation, encapsulant 937 can be coplanar with the lateral sides of substrate 902, the lateral sides of substrate 904, and the lateral sides of intermediate substrate 919.

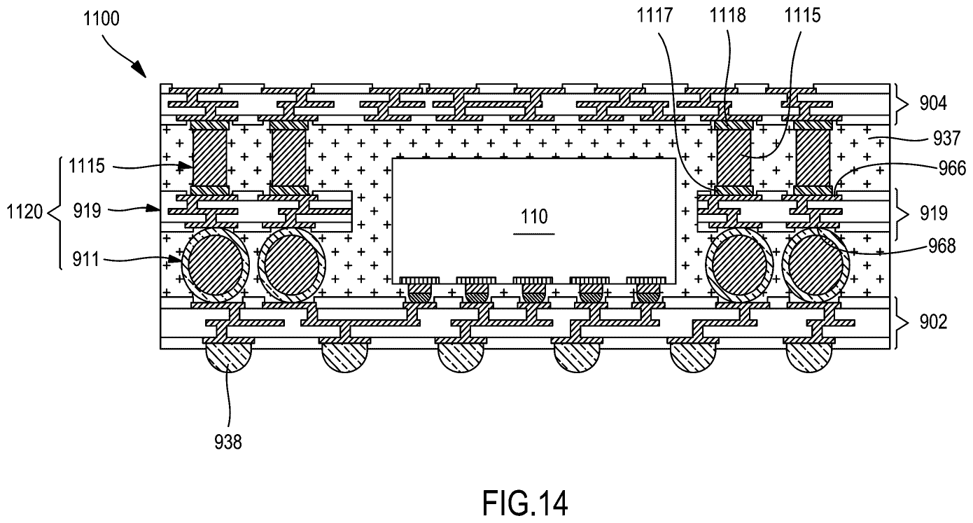

Referring now to FIG. 14, example electronic device 1100 is shown in cross section, in accordance with various examples. Example electronic device 1100 can comprise structures and manufacturing techniques similar to or the same as those of electronic device 900, electronic device 900′, or other electronic devices described herein. Electronic device 1100 can comprise substrate 902, substrate 904, electronic component 110, encapsulant 937, and vertical interconnects 1120. In some examples electronic device 1100 can also comprise external interconnects 938.

In accordance with various examples, vertical interconnect 1120 can comprise interconnect structure 911, as previously described, intermediate substrate 919, as previously described, and interconnect structure 1115. For example, in vertical interconnect 1120, interconnect structure 915 (as depicted in 11C and 13A) can be replaced with interconnect structure 1115. Interconnect structure 1115 can comprise a pillar, via, post, pin, or other narrow interconnect. In some examples, a height to width ratio of interconnect structure 1115 can be between 2:1 and 20:1, or between 4:1 and 15:1. For example, interconnect structure 1115 can have a height to width ratio of at least 2:1, 3:1, 4:1 10:1 or 16:1

In some examples, interconnect structure 1115 can be coupled to intermediate substrate 919 by flowable material 1117 and to substrate 904 by flowable material 1118. In some examples, flowable material 1117 or flowable material 1118 can be omitted and interconnect structure 1115 can be coupled directly to intermediate substrate 919 or substrate 904, respectively. For example, interconnect structures 1115 can be formed by plating a metal (e.g., Cu) on inner terminals 905 of substrate 904 or on inner terminals 968 of intermediate substrate 919. In some examples, interconnect structure 911 of vertical interconnect 1120 can be replaced by a narrow interconnect similar to interconnect structure 1115, such that both interconnect structure 911 and interconnect structure 1115 include narrow interconnects. In some examples, interconnect structure 911 of vertical interconnect 1120 can be replaced by a narrow interconnect similar to interconnect structure 1115 and interconnect structure 1115 can be replaced by an interconnect having a core ball (e.g., spherical) structure, similar to interconnect structure 911.

In some example, interconnect structure 1115 can be aligned vertically over interconnect structure 911. In some examples, interconnect structure 1115 can be staggered relative to interconnect structure 911 so that the interconnect structures are not vertically aligned. Vertical interconnect 1120 can include the pins of interconnect structure 1115, the conductive structures of intermediate substrate 919, and interconnect structure 911. Encapsulant 937, as previously described, can be disposed around the interconnect structures 1115 and interconnect structures 911.

In accordance with various examples, vertical interconnects 1120 can be provided with a fine interconnect pitch while supporting increased height of vertical interconnects 1120. The thickness of electronic component 110 can be increased, as the volume between substrate 904 and substrate 902 is increased by increasing the height of vertical interconnect 1120. In some examples, the height of electronic component 110 can approach (e.g., be less than, or equal to) the height of vertical interconnect 1120. Thicker electronic components 110 can result in improved thermal performance in some examples.

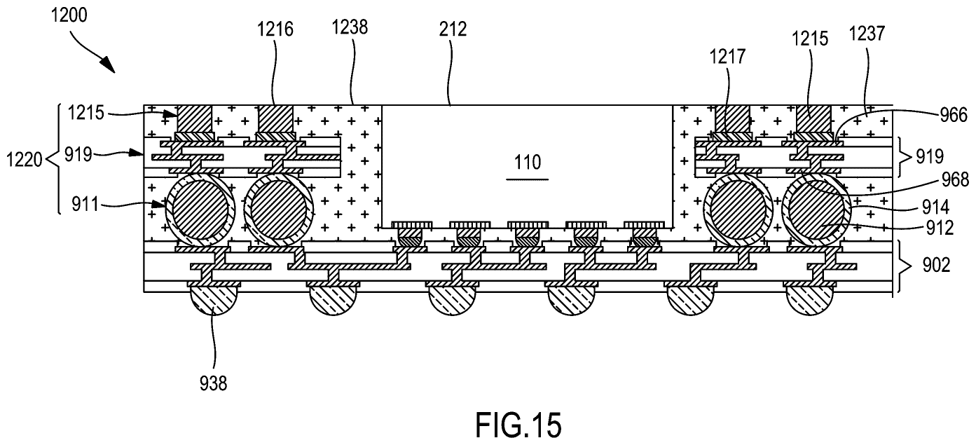

Referring now to FIG. 15, an example electronic device 1200 is shown in cross section, in accordance with various examples. Example electronic device 1200 can comprise structures and manufacturing techniques similar to or the same as those of electronic device 900, electronic device 900′, electronic device 1100, or other electronic devices described herein. Electronic device 1200 can include substrate 902, vertical interconnect 1220, electronic component 110, and encapsulant 1237. In some examples, electronic device 1200 can include external interconnects 938.

In accordance with various examples, vertical interconnect 1220 of electronic device 1200 can include interconnect structures 911, as previously described, intermediate substrate 919, as previously described, and interconnect structures 1215. In some examples, interconnect structure 1215 can be similar to or the same as interconnect 1115 of electronic device 1100 in FIG. 14. In some examples, fusible material 1217 can couple interconnect structure 1215 to inner terminals 966 of intermediate substrate 919. In accordance with various examples, a distal side 1216 of interconnect structure 1215 can be exposed at an external (e.g., an upper) side of electronic device 1200. For example, distal side 1216 of interconnect structure 1215 can be exposed from side 1238 of encapsulant 1237. In some examples, side 1238 of encapsulant 1237 can be coplanar with distal side 1216 of interconnect structure 1215. In some examples, backside 212 of electronic component 110 can be exposed at and/or coplanar with side 1238 of encapsulant 1237.

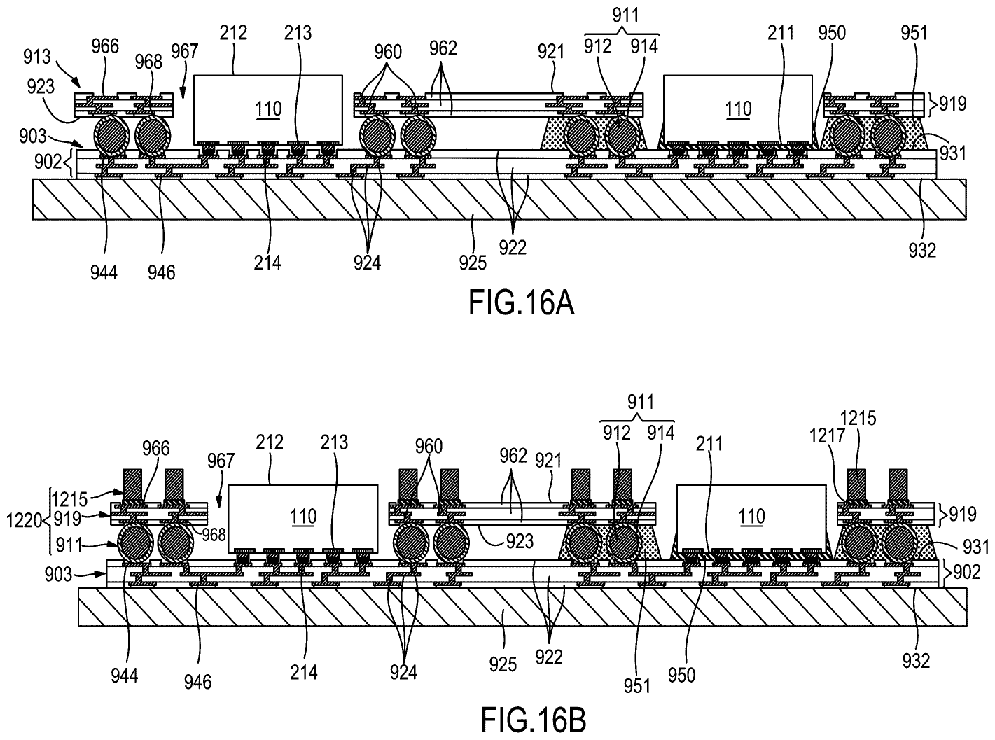

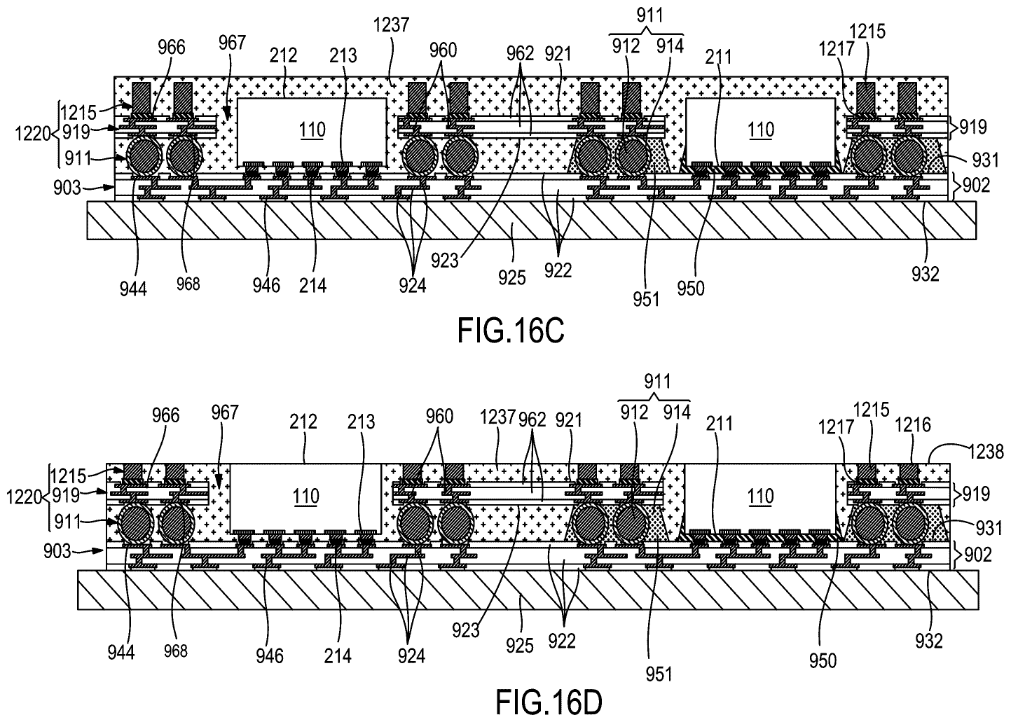

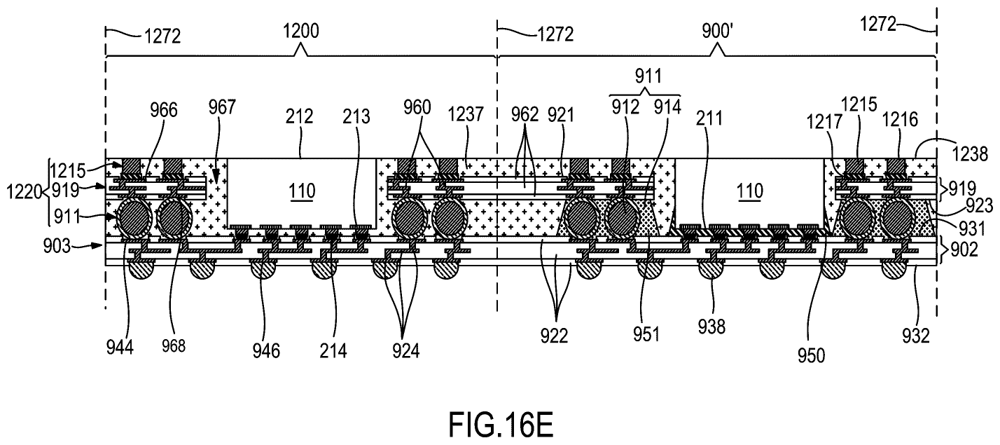

FIGS. 16A-16E depict an example method of manufacturing electronic device 1200, in accordance with various examples. The example of FIG. 16A can continue from steps depicted in FIGS. 11A and 11E. In the example of FIG. 16A, intermediate substrates 919 can be disposed over and coupled to substrates 902. In some examples, intermediate substrates 919 can be provided over and coupled to substrates 902 in the form of substrate strip 913. In some examples, intermediate substrates 919 can be disposed over and coupled to substrates 902 as separate, discrete substrates (e.g., after singulation of substrate strip 913), as shown FIG. 11F. Fusible material 914 of interconnect structure 911 can couple core structure 912 of interconnect structure 911 to outer terminals 968 of intermediate substrate 919 and to inner terminals 944 of substrate 902. Electronic component 110 is coupled to inner terminals 944 of substrate 902 and can be located in openings 967 of intermediate substrates 919.

FIG. 16B shows electronic device 1200 at a later stage of manufacture, in accordance with various examples. In the example of FIG. 16B, interconnect structures 1215 can be provided over intermediate substrate 919.

In accordance with various examples, interconnect structures 1215 can be provided over inner side 921 of intermediate substrate 919. Interconnect structures 1215 can be coupled to inner terminals 966 of conductive structure 960. Interconnect structures 1215 can comprise Cu, Al, Sn, Ti, TiW, Au, Ag, Ni, Pd, or combinations or alloys thereof. In some examples, interconnect structures 1215 can be pre-formed structures that are formed prior to being coupled to intermediate substrate 919. Such preformed interconnect structures can be coupled to inner terminals 966 via fusible material 1217 (e.g., via a conductive material such as solder or conductive adhesive). In some example, interconnect structures 1215 can comprise plated pillars. For example, interconnect structures 1215 can be formed by plating Cu on inner terminals 966 of intermediate substrate 919. Interconnect structures 1215 can comprise or be referred to as preformed posts or pins, plated pillars, vertical wires, one or more stacked bumps or solder-coated-metallic-core-interconnects (e.g., solder coated Cu balls or solder coated Cu pins) or other vertical interconnect structure. In some examples, interconnect structures 1215 comprise narrow interconnects. In some examples, a height to width ratio of interconnect structure 1215 can be between 2:1 and 20:1, or between 4:1 and 15:1. For example, interconnect structure 1215 can have a height to width ratio of at least 2:1, 3:1, 4:1 10:1 or 16:1. In some examples, interconnect structures 1215 can be formed on outer terminals 906 of intermediate substrates 919 before coupling to substrate 902.

In various examples, interconnect structures 1215 can protrude above back side 212 of electronic component 110. Vertical interconnect structure 1220 can comprise interconnect structures 1215, intermediate substrates 919, and interconnect structures 911.

FIG. 16C shows electronic device 1200 at a later stage of manufacture, in accordance with various examples. In the example of FIG. 16C, encapsulant 1237 can be provided. Encapsulant 1237 can comprise structures or manufacturing techniques similar to or the same as encapsulant 137, encapsulant 937 or any other encapsulant described herein.

In some examples, encapsulant 1237 can completely cover interconnect structures 1215 and backside 212 of electronic component 110. Encapsulant 1237 can be disposed in opening 967 of intermediate substrate 919 and around the lateral sides of electronic component 110. In some examples, encapsulant 1237 can be between front side 211 of electronic component 110 and inner side 931 of substrate 902.

FIG. 16D shows electronic device 1200 at a later stage of manufacture, in accordance with various examples. In the example of FIG. 16D, a portion of encapsulant 1237 is removed, exposing interconnect structures 1215.

In accordance with various examples, encapsulant 1237 can be thinned using a back-grinding process, laser ablation, chemical etching, or any other suitable encapsulant removal process. The back-grinding process can expose distal side 1216 of interconnect structures 1215. In some examples, interconnect structures 1215 can also be thinned (i.e., a portion can be removed) in the back-grinding process. In some examples, the grinding process can include a coarse grinding process to rapidly reduce the thickness of encapsulant 1237 in an initial stage, and then a fine grinding process to more precisely and finely grind encapsulant 1237 to reduce surface roughness and reach a desired thickness.

In some examples, after the removal process, exposed distal side 1216 of interconnect structures 1215 and upper side 1238 of encapsulant 1237 can be coplanar. In some examples, the removal of encapsulant 1237 can expose backside 212 of electronic device 110. For example, backside 212 of electronic component 110 can be coplanar with upper side 1238 of encapsulant 1237. In some examples, backside 212 of electronic device 110 can remain covered by encapsulant 1237 (e.g., distal side 1216 of interconnect structure 1215 and upper side 1238 of encapsulant 1237 can be above back side 212)

FIG. 16E shows electronic device 1200 at a later stage of manufacture, in accordance with various examples. In the example of FIG. 16E, carrier 925 can be removed and external interconnects 938, as previously described, can be provided. can be provided over outer side 933 of substrate 902. External interconnects 938 can be coupled to outer terminals 946 of conductive structure 924.

In the example of FIG. 16E, singulation can also be performed. In some examples, singulation can be performed after providing external interconnects 938. In various examples, singulation can be performed by sawing or otherwise cutting through saw streets, for example indicated by lines 1272, disposed around a perimeter of electronic devices 1200, thereby separating individual electronic devices 1200 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate strip 913, substrate strip 903, and encapsulant 1237. In some examples, after singulation, encapsulant 1237 can be coplanar with the lateral sides of substrate 902 and the lateral sides of intermediate substrate 919. In some examples, intermediate substrates 919 can be provided as discrete, singulated substrate 919 such that encapsulant 1237 extends between adjacent intermediate substrate 919. In such examples, after singulation through saw streets 1272, encapsulant 1237 can surround intermediate substrate 919 in electronic device 1200, similar to encapsulant 937 of electronic device 900 in FIG. 10.

Electronic devices and related manufacturing techniques can use tall, narrow vertical interconnects to increase die thickness while maintaining fine pitch. Pins, pillars, balls, or other interconnect structures can be stacked to form tall vertical interconnects that can conduct electronic signals around the lateral sides of tall or thick electronic components. Thicker die can be incorporated into electronic devices, and thicker die can result in improved thermal performance relative to thinner die. By increasing the height of vertical interconnects, the improved thermal performance of thicker die can be realized in electronic devices. Arranging tall vertical interconnects in a configuration with fine pitch can also maintain good input/output performance.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a first substrate;
an electronic component disposed over a side of the first substrate;
a vertical interconnect structure coupled to the side of the first substrate, the vertical interconnect structure comprising:
a first metallic core structure coupled to the side of the first substrate;
a second metallic core structure coupled to the first metallic core structure;
a fusible material coupling the first metallic core structure with the second metallic core structure, wherein the fusible material couples the first metallic core structure to the first substrate; and
a second substrate disposed over the electronic component and the vertical interconnect structure, wherein the second metallic core structure of the vertical interconnect structure is coupled to the second substrate by the fusible material; and
an encapsulant disposed over the electronic component, around the first metallic core structure and the second metallic core structure, and between the first substrate and the second substrate.

2. The electronic device of claim 1, wherein the first metallic core structure comprises a first pin.

3. The electronic device of claim 2, wherein the second metallic core structure comprises a second pin.

4. The electronic device of claim 2, wherein the second metallic core structure comprises a ball.

5. The electronic device of claim 1, wherein the first metallic core structure comprises a ball.

6. The electronic device of claim 1, wherein the first metallic core structure and the second metallic core structure comprise copper.

7. The electronic device of claim 1, wherein a portion of the fusible material coupling the first metallic core structure with the second metallic core structure is disposed lateral to a sidewall of the electronic component.

8. The electronic device of claim 7, wherein the encapsulant is coupled to the portion of the fusible material coupling the first metallic core structure with the second metallic core structure.

9. An electronic device, comprising:
a first substrate;
an electronic component disposed over the first substrate;
a first interconnect structure coupled to the first substrate lateral to the electronic component;
a second interconnect structure coupled to the first interconnect structure;
a fusible material coupling the first interconnect structure with the second interconnect structure and coupling the first interconnect structure with the first substrate; and
a second substrate disposed over the electronic component and the second interconnect structure, wherein the second interconnect structure is coupled to the second substrate by the fusible material.

10. The electronic device of claim 9, wherein the first interconnect structure comprises a first metallic core pin.

11. The electronic device of claim 10, wherein the second interconnect structure comprises a second metallic core pin.

12. The electronic device of claim 10, wherein the second interconnect structure comprises a metallic core ball.

13. The electronic device of claim 10, wherein a portion of the fusible material coupling the first interconnect structure with the second interconnect structure is disposed lateral to a sidewall of the electronic component.

14. The electronic device of claim 9, further comprising an underfill disposed between the electronic component and the first substrate.

15. The electronic device of claim 9, wherein the electronic component is in electronic communication with the second substrate through the first substrate, the first interconnect structure, and the second interconnect structure.

16. A method of manufacturing an electronic device, comprising:
providing a first substrate;
providing an electronic component coupled to the first substrate;
providing a first interconnect structure coupled to the first substrate lateral to the electronic component;
providing a second substrate comprising a second interconnect structure coupled to the second substrate;
aligning the first substrate and second substrate with the first interconnect structure over the second interconnect structure; and
coupling the first interconnect structure with the second interconnect structure using a fusible material.

17. The method of claim 16, wherein the first interconnect structure comprises a first metallic core pin.

18. The method of claim 16, wherein the second interconnect structure comprises a second metallic core pin.

19. The method of claim 16, wherein the second interconnect structure comprises a metallic core ball.

20. The method of claim 16, further comprising providing an encapsulant around sides of the first interconnect structure and the second interconnect structure, between the first interconnect structure and the electronic component, and between the electronic component and the second substrate.
